(19) United States
(12) Patent Application Publication
(10) Pub. No.: US 2025/0318447 A1
(43) Pub. Date: Oct. 9, 2025

(54) THERMAL BARRIER STRUCTURE IN PHASE CHANGE MATERIAL DEVICE

(71) Applicant: Taiwan Semiconductor Manufacturing Company, Ltd., Hsinchu (TW)

(72) Inventor: Tsung-Hsueh Yang, Taichung City (TW)

(21) Appl. No.: 19/243,074

(22) Filed: Jun. 19, 2025

Related U.S. Application Data
(63) Continuation of application No. 18/150,903, filed on Jan. 6, 2023.
(60) Provisional application No. 63/416,645, filed on Oct. 17, 2022.

(51) Int. Cl. H10N 70/20; H10N 70/00

(52) U.S. Cl. CPC H10N 70/231; H10N 70/063; H10N 70/8616; H10N 70/8828

(57) ABSTRACT

The present disclosure is directed towards an integrated chip including a heater structure overlying a semiconductor substrate. A phase change element (PCE) is disposed over the heater structure. A thermal barrier structure is disposed between the heater structure and the PCE. Outer sidewalls of the PCE are spaced laterally between outer sidewalls of the thermal barrier structure.

### REFERENCE TO RELATED APPLICATIONS

This Application is a Continuation of U.S. application Ser. No. 18/150,903, filed on Jan. 6, 2023, which claims the benefit of U.S. Provisional Application No. 63/416,645, filed on Oct. 17, 2022. The contents of the above-referenced Patent Applications are hereby incorporated by reference in their entirety.

### BACKGROUND

Modern day integrated circuits (ICs) comprise millions or billions of semiconductor devices formed on a semiconductor substrate (e.g., silicon). ICs may use many different types of transistor devices, depending on application. In recent years, the increasing market for cellular and radio frequency (RF) devices has resulted in a significant increase in the demand for RF switch devices. For example, a smartphone may incorporate ten or more RF switch devices to switch a received signal to appropriate bands.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate various views of some embodiments of a phase change material (PCM) device having a thermal barrier structure configured to increase a performance of the PCM device.

FIGS. 2A-2C and 3A-3C illustrate various views of some other embodiments of the PCM device of FIGS. 1A-1B.

FIGS. 4A-4C illustrate various views of some alternative embodiments of the PCM device of FIGS. 1A-1B, where a sidewall spacer structure is disposed along sidewalls of a phase change element (PCE) of the PCM device.

FIGS. 5A-5B and 6A-6B illustrate various cross-sectional views of some other embodiments of the PCM device of FIGS. 4A-4C.

FIGS. 7A-7B illustrate various views of some embodiments of an integrated chip having a PCM device comprising a thermal barrier structure disposed within an interconnect structure.

FIGS. 8A-8B illustrate various cross-sectional views of some other embodiments of the integrated chip of FIGS. 7A-7B.

FIGS. 9A-9C illustrate various views of some other embodiments of the integrated chip of FIGS. 7A-7B, where a sidewall spacer structure is disposed along sidewalls of a PCE of the PCM device.

FIGS. 10A-10C illustrate various views of some other embodiments of the PCM device of FIGS. 4A-4C.

FIGS. 11A-11B and 12A-12B illustrate various cross-sectional views of some other embodiments of the PCM device of FIGS. 10A-10C.

FIG. 13 illustrates a graph corresponding to some different embodiments of performance examples of a PCM device having a thermal barrier structure.

FIGS. 14A-14C through 23A-23C illustrate various views of some embodiments of a method for forming an integrated chip comprising a PCM device having a thermal barrier structure configured to increase a performance of the PCM device.

FIG. 24 illustrates a methodology in flowchart format of some embodiments of a method for forming an integrated chip comprising a PCM device having a thermal barrier structure configured to increase a performance of the PCM device.

FIGS. 25A-25C through 31A-31C illustrate various views of some embodiments of a method for forming an integrated chip comprising a PCM device having a thermal barrier structure and a sidewall spacer structure configured to increase a performance of the PCM device.

FIG. 32 illustrates a methodology in flowchart format of some embodiments of a method for forming an integrated chip comprising a PCM device having a thermal barrier structure and a sidewall spacer structure configured to increase a performance of the PCM device.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A phase change material (PCM) device may include a phase change element (PCE) disposed over a heater structure. The PCE has a crystalline phase and an amorphous phase with different electrical resistivity values, such that the PCM device is configured to switch between discrete resistive states. During operation of the PCM device, the heater structure is configured to generate heat, based on an applied switching signal (e.g., a voltage or current signal), that adjusts the phase of the PCE. For example, the PCM device may be switched to a first state (e.g., an “OFF” state) by heating the PCE to a high temperature (e.g., by applying a high current and/or voltage to the heater structure) and subsequently cooling the PCE after heating it. The heating and cooling causes the PCE to be in the amorphous phase (e.g., corresponding to a high resistance state). Further, the PCM device may be switched to a second state (e.g., an “ON” state) by heating the PCE to a moderate temperature (e.g., by applying a moderate voltage and/or current to the heater structure) for an extended period of time. This causes the PCE to be in the crystalline phase (e.g., corresponding to a low resistance state). Thus, the switching operation of the PCM device is dependent upon a temperature applied to the PCE by the heater structure.

The PCM device may further comprise a thermal barrier structure disposed between the PCE and the heater structure. The thermal barrier structure is configured to increase a distance between the heater structure and the PCE (i.e., increasing isolation between the PCE and the heater structure) and/or more uniformly distribute heat generated by the heater structure across the PCE, thereby mitigating damage to the PCE during switching operations. The PCE and the thermal barrier structure may be formed by a single etch process such that outer sidewalls of the PCE are aligned with outer sidewalls of the thermal barrier structure. The thermal barrier structure may adjust a breakdown voltage of the PCM device, for example, by adjusting a thickness, layout, and/or material of the thermal barrier structure. In addition, the heater structure may comprise a middle heater segment continuously extending between a first outer heater segment and a second outer heater segment. The PCE and thermal barrier structure directly overlies the middle heater segment such that the outer sidewalls of the PCE and the thermal barrier structure directly overlie outer regions of the middle heater segment. During operation of the PCM device, a switching signal (e.g., a current and/or voltage signal) is applied across the middle heater segment of the heater structure to heat and adjust the phase of the PCE. However, high heat may accumulate at the outer regions of the middle heater segment. Because the outer sidewalls of the PCE and the thermal barrier structure are aligned at the outer regions of the middle heater segment, the high heat is not uniformly distributed across the PCE and the PCE may be damaged at relatively low voltages (e.g., around 7 volts). For example, the high heat at the outer regions of the middle heater segment may cause warping, cracking, or peeling of the PCM and/or thermal barrier structure around the outer sidewalls of the PCE, thereby reducing a breakdown voltage of the PCM device (e.g., reducing the breakdown voltage to around 7 volts). As a result, an operating voltage range, stability, and an overall performance of the PCM device are reduced.

Various embodiments of the present disclosure are directed towards PCM device having a thermal barrier structure configured to increase performance of the PCM device. The PCM device overlies a substrate. The PCM device comprises a PCE and a heater structure having a middle heater segment continuously extending between a first outer heater segment and a second outer heater segment. The PCE directly overlies the middle heater segment and has outer sidewalls overlying outer regions of the middle heater segment. Further, a thermal barrier structure is disposed between the PCE and the heater structure. The outer sidewalls of the PCE are spaced between outer sidewalls of the heater barrier structure such that the thermal barrier structure extends outward from the outer sidewalls of the PCE. As a result, the thermal barrier structure increases isolation between the heater structure and the PCE (e.g., at the outer regions of the middle heater segment) and increases uniform distribution of heat from the heater structure across the PCE. This prevents damage to the PCE during switching operations and increases a breakdown voltage of the PCM device (e.g., to above about 14 volts). Thus, the thermal barrier structure increases an operating voltage range, stability, endurance, and overall performance of the PCM device.

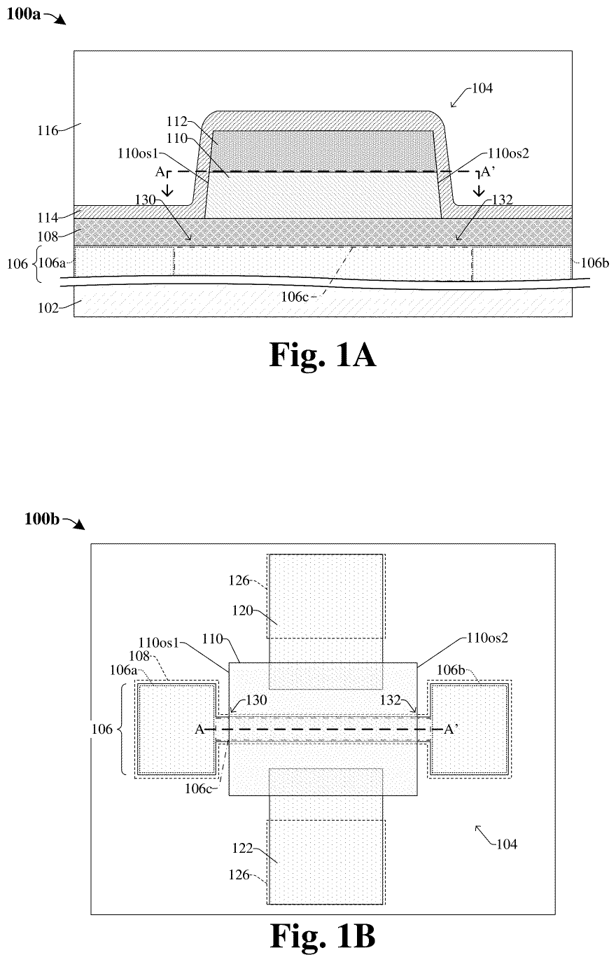

FIGS. 1A and 1B illustrate various views of some embodiments of an integrated chip including a PCM device 104 having a thermal barrier structure 108 configured to increase a performance of the PCM device 104. FIG. 1A illustrates cross-sectional view 100a corresponding to some embodiments of the integrated chip. FIG. 1B illustrates top view 100b corresponding to some embodiments of the integrated chip taken along line A-A′ of the cross-sectional view 100a of FIG. 1A.

The integrated chip includes a PCM device 104 overlying a semiconductor substrate 102. In some embodiments, the PCM device 104 comprises a heater structure 106, a thermal barrier structure 108, a phase change element (PCE) 110, and a hard mask 112. The thermal barrier structure 108 is disposed between the PCE 110 and the heater structure 106. The hard mask 112 overlies the PCE 110. An upper dielectric layer 116 is disposed over and around the PCM device 104 and a capping layer 114 is disposed between the upper dielectric layer 116 and the PCM device 104. The capping layer 114 continuously extends from outer sidewalls 110os1, 110os2 of the PCE 110, along outer sidewalls of the hard mask 112, to an upper surface of the hard mask 112.

In some embodiments, the PCE 110 may comprise a PCM such as one or more chalcogenide material(s) that comprise at least one chalcogen ion (e.g., a chemical element in column VI of the periodic table), germanium antimony telluride (GST), another suitable phase-change alloy, or some other suitable material. The PCE 110 may have a crystalline phase or an amorphous phase with different electrical resistivity values that may be adjusted based on a heat applied to the PCE 110. During operation of the PCM device 104, the heater structure 106 is configured to generate heat based on an applied switching signal (e.g., a voltage or current signal) that adjusts the phase of the PCE 110. For example, the PCM device 104 may be switched to a first state (e.g., an “OFF” state) by heating the PCE 110 to a high temperature (e.g., about 700 degrees Celsius) and subsequently cooling the PCE 110. The heating to the high temperature and subsequent cooling causes the PCE 110 to be in the amorphous phase (e.g., corresponding to a high resistance state). Further, the PCM device 104 may be switched to a second state (e.g., an “ON” state) by heating the PCE 110 to a moderate temperature (e.g., over about 200 degrees Celsius, or within a range of about 200 to 300 degrees Celsius) for an extended period of time. The heating at the moderate temperature causes the PCE 110 to be in the crystalline phase (e.g., corresponding to a low resistance state). Thus, the switching operation of the PCM device 104 is dependent upon a temperature applied to the PCE 110 by the heater structure 106. In some embodiments, the PCE 110 is referred to as or configured as a switching layer, a data storage layer, or the like. In further embodiments, the PCM device 104 may be configured as a PCM switch, an RF switch, a PCM memory device, or the like.

The heater structure 106 comprises a first outer heater segment 106a, a second outer heater segment 106b, and a middle heater segment 106c continuously laterally extending between the first outer heater segment 106a to the second outer heater segment 106b. During operation of the PCM device 104, the switching signal is applied to the first outer heater segment 106a and/or the second outer heater segment 106b across the middle heater segment 106c, thereby generating heat at the middle heater segment 106c. At least a middle region of the PCE 110 directly overlies the middle heater segment 106c such that the heat generated at the middle heater segment 106c may adjust the phase of the PCE. The thermal barrier structure 108 is disposed vertically between the heater structure 106 and the PCE 110. The thermal barrier structure 108 is configured to increase a distance between the heater structure 106 and the PCE 110 and/or more uniformly distribute heat generated by the heater structure 106 across the PCE 110, thereby mitigating damage to the PCE 110 during switching operations. Further, outer sidewalls of the thermal barrier structure 108 extend past the outer sidewalls 110os1, 110os2 of the PCE 110. In some embodiments, as illustrated in top view 100b of FIG. 1B, the thermal barrier structure 108 comprises a same shape as the heater structure 106 and has a larger size than the heater structure 106 that directly overlies an outer perimeter of the heater structure 106.

In various embodiments, during operation of the PCM device 104, high heat (e.g., about 600 to 700 degrees Celsius or higher) may accumulate at outer regions 130, 132 of the middle heater segment 106c (e.g., during a switching operation). By virtue of the outer sidewalls 110os1, 110os2 of the PCE 110 being disposed between the outer sidewalls of the thermal barrier structure 108, the thermal barrier structure 108 may provide increased isolation between the PCE 110 and the heater structure 106 at the outer regions 130, 132 of the middle heater segment 106c. As a result, the thermal barrier structure 108 mitigates damage (e.g., warping, cracking, peeling, etc.) to the PCE 110 during switching operations, thereby increasing a breakdown voltage of the PCM device 104 (e.g., to above about 14 volts). Thus, the thermal barrier structure 108 increases a stability, endurance, and overall performance of the PCM device 104.

With reference to the top view 100b of FIG. 1B, the PCM device 104 further comprises a first radio frequency (RF) structure 120 and a second RF structure 122. It will be appreciated that for ease of illustration the PCE 110 is at least partially transparent, an outer perimeter of the thermal barrier structure 108 is represent by dashes, and the capping layer 114 is omitted in the top view 100b of FIG. 1B. Further, an etch stop layer 126 is disposed along top surfaces of the first and second RF structures 120, 122. The first and second RF structures 120, 122 are configured to perform a read operation on the PCM device 104. For example, the first RF structure 120 is configured to transmit an RF signal through the PCE 110 to the second RF structure 122. In various embodiments, a strength of the RF signal as received by the second RF structure 122 is dependent on the phase of the PCE 110. For instance, when the RF signal is transmitted from the first RF structure 120 through the PCE 110 while the PCE 110 is in the amorphous phase, a strength of the RF signal (e.g., a received signal strength) received at the second RF structure 122 may be relatively low. In another example, when the RF signal is transmitted from the first RF structure 120 through the PCE 110 while the PCE is in the crystalline phase, a strength of the RF signal received at the second RF structure 122 may be relatively high. In further embodiments, the RF signal may pass through the PCE 110 or will not pass through the PCE 110 based on the phase of the PCE 110. In yet further embodiments, the second RF structure 122 may be configured to transmit the RF signal to the first RF structure 120 and the first RF structure 120 is configured to receive the RF signal. Accordingly, the first and second RF structures 120, 122 are configured to perform non-destructive read operations on the PCM device 104 and determine a state of the PCM device 104.

In yet further embodiments, due to a layout and/or proximity between the heater structure 106 and the first and/or second RF structures 120, 122, leakage may occur between the first and/or second RF structures 120, 122 and the heater structure 106 (e.g., such as the first and/or second outer heater segments 106a, 106b) during the read operation. This may, in part, may result in inaccurate read operations (e.g., because the heater structure 106 interferes with the RF signal). By virtue of a material, layout, thickness, and/or area of the thermal barrier structure 108, the thermal barrier structure 108 increases isolation between the first and/or second RF structures 120, 122 and the heater structure 106, thereby decreasing leakage between the first and/or second RF structures 120, 122 and the heater structure 106. As a result, read operations may be accurately performed on the PCM device 104, thereby increasing an overall performance of the PCM device 104.

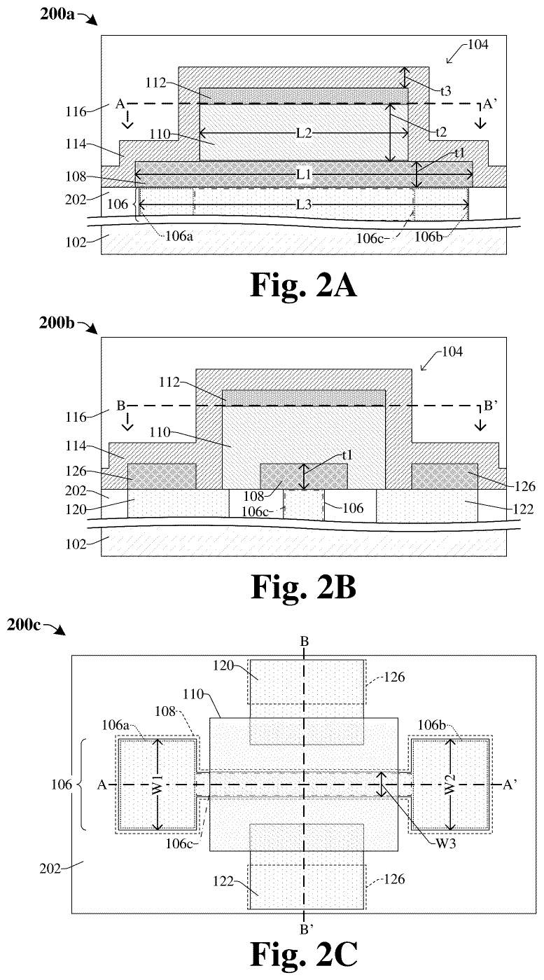

FIGS. 2A-2C illustrate various views of some embodiments of an integrated chip including a PCM device 104 having a thermal barrier structure 108 configured to increase a performance of the PCM device 104. FIG. 2A illustrates cross-sectional view 200a corresponding to some embodiments of the integrated chip taken along the line A-A′ of a top view 200c of FIG. 2C. FIG. 2B illustrates cross-sectional view 200b corresponding to some embodiments of the integrated chip taken along the line B-B′ of the top view 200c of FIG. 2C.

The integrated chip comprises a PCM device 104 overlying a semiconductor substrate 102. The semiconductor substrate 102 may, for example, be or comprise silicon, monocrystalline silicon, a bulk substrate, a silicon-on-insulator (SOI) substrate, some other suitable substrate, or the like. The PCM device 104 comprises a heater structure 106, a thermal barrier structure 108, a PCE 110, and a hard mask 112. The thermal barrier structure 108 is disposed vertically between the PCE 110 and the heater structure 106. The heater structure 106 may, for example, be or comprise tungsten, titanium, titanium nitride, molybdenum, some other conductive material, or any combination of the foregoing. The thermal barrier structure 108 may, for example, be or comprise silicon nitride, silicon carbide, aluminum nitride, a high-k dielectric material, some other suitable material, or any combination of the foregoing. As used herein, a high-k dielectric material is a dielectric material with a dielectric constant greater than about 3.9. The hard mask 112 may, for example, be or comprise silicon nitride, silicon carbide, silicon dioxide, some other dielectric material, or any combination of the foregoing. In yet further embodiments, the hard mask 112 may comprise a first hard mask layer (not shown) disposed on the PCE and a second hard mask layer (not shown) on the first hard mask layer. In such embodiments, the first hard mask layer may comprise a first dielectric material (e.g., silicon nitride, silicon carbide, etc.) and the second hard mask layer may comprise a second dielectric material (e.g., an oxide, silicon dioxide, etc.).

The heater structure 106 is disposed within a lower dielectric layer 202. Further, an upper dielectric layer 116 overlies the PCM device 104. The lower dielectric layer 202 and the upper dielectric layer 116 may, for example, each be or comprise silicon dioxide, a low-k dielectric material, an extreme low-k dielectric material, some other dielectric material, or any combination of the foregoing. As used herein, a low-k dielectric material is a dielectric material with a dielectric constant less than about 3.9. A capping layer 114 is disposed between the upper dielectric layer 116 and the PCM device 104. The capping layer 114 may comprise a non-oxygen based dielectric material, some other dielectric material, or any combination of the foregoing. The non-oxygen based dielectric material may, for example, be silicon nitride, silicon carbide, or the like.

Further, the heater structure 106 comprises a first outer heater segment 106a, a second outer heater segment 106b, and a middle heater segment 106c. The middle heater segment 106c is disposed laterally between the first outer heater segment 106a and the second outer heater segment 106b. The PCE 110 and the hard mask 112 directly overlie the middle heater segment 106c and are spaced laterally between the first and second outer heater segments 106a, 106b. Further a first radio frequency (RF) structure 120 and a second RF structure 122 is disposed within the lower dielectric layer 202. The middle heater segment 106c is disposed laterally between the first RF structure 120 and the second RF structure 122. The first and second RF structures 120, 122 may, for example, each be or comprise tungsten, aluminum, copper, titanium nitride, another conductive material, or any combination of the foregoing. In various embodiments, the heater structure 106 may comprise a first conductive material (e.g., tungsten) and the first and second RF structures 120, 122 may comprises a second conductive material (e.g., copper, aluminum, etc.) different from the first conductive material. Further, an etch stop layer 126 directly overlies the first and second RF structures 120, 122. The etch stop layer 126 may, for example, be or comprise silicon nitride, silicon carbide, aluminum nitride, some other dielectric material, or any combination of the foregoing.

With reference to the cross-sectional view 200a of FIG. 2A, in some embodiments, the thermal barrier structure 108 has a first length L1 that is greater than a second length L2 of the PCE 110. Further, the heater structure 106 has a third length L3 that is less than the first length L1 and greater than the second length L2. In various embodiments, by virtue of the thermal barrier structure 108 having the first length L1 that is greater than the second length L2 of the PCE 110, the thermal barrier structure 108 may provide increased isolation between the PCE 110 and the heater structure 106 (e.g., at outer regions of the middle heater segment 106c). As a result, damage (e.g., peeling and/or lifting of outer edges of the PCE 110 at high heat) to the PCE 110 during operation of the PCM device 104 is reduced.

Further, the thermal barrier structure 108 has a first thickness t1 that may, for example, be within a range of about 300 angstroms to about 600 angstroms, or some other suitable value. In various embodiments, if the first thickness t1 is sufficiently thick (e.g., about 300 angstroms or more), the PCE 110 is sufficiently isolated from relatively high heat during operation of the PCM device 104 and/or the thermal barrier structure 108 may more effectively distribute heat uniformly across the PCE 110, thereby increasing an endurance (e.g., a number of switching operations that may be performed) of the PCM device 104. In yet further embodiments, if the first thickness t1 is less than about 600 angstroms, then a heat transfer efficiency between the heater structure 106 and the PCE 110 is increased, thereby reducing power utilized during read and/or switching operations performed on the PCM device 104. In some embodiments, the PCE 110 has a second thickness t2 that may, for example be within a range of about 500 angstroms to about 1,000 angstroms, or some other suitable value. In further embodiments, the first thickness t1 of the thermal barrier structure 108 is less than the second thickness t2 of the PCE 110. In yet further embodiments, the capping layer 114 has a third thickness t3 that may, for example, be within a range of about 100 angstroms to about 400 angstroms. In various embodiments, the third thickness t3 may be less than the first thickness t1 and may be less than the second thickness t2.

With reference to the cross-sectional view 200b of FIG. 2B, the thermal barrier structure 108 extends laterally past outer sidewalls of the middle heater segment 106c of the heater structure 106. Further, the etch stop layer 126 overlies outer regions of the first and second RF structures 120, 122. In various embodiments, a thickness of the etch stop layer 126 is equal to the first thickness t1 of the thermal barrier structure 108. In some embodiments, the etch stop layer 126 comprises a same material as the thermal barrier structure 108. Further, the PCE 110 may continuously extend from opposing sidewalls of the thermal barrier structure 108 to a top surface of the thermal barrier structure 108. A bottom surface of the PCE 110 may be aligned with a bottom surface of the thermal barrier structure 108. In addition, the PCE 110 directly overlies portions of the first and second RF structures 120, 122.

With reference to the top view 200c of FIG. 2C, the thermal barrier structure 108 and the heater structure 106 have a same shape and/or layout, where the thermal barrier structure 108 has a greater area than the heater structure 106 when viewed from above. In such embodiments, the thermal barrier structure 108 continuously extends laterally outward from an outer perimeter of the heater structure 106. Further, the first outer heater segment 106a has a first width W1 and the second outer heater segment 106b has a second width W2. The middle heater segment 106c has a third width W3 that may be less than the first width W1 and the second width W2. In various embodiments, by virtue of the first and second widths W1, W2 being relatively large (e.g., at least two times greater than the third width W3) the first and second outer heater segments 106a, 106b may be sufficiently large to have one or more conductive vias (not shown) formed on the first and second outer heater segments 106a, 106b. Further, the relatively large first and second widths W1, W2 facilitates receiving a large enough voltage to induce current generating heat. In various embodiments, the third width W3 being relatively small (e.g., at least half the size of the first or second widths W1, W2) ensures the middle heater segment 106c may generate sufficient heat that is directed towards the PCE 110. In various embodiments, the third width W3 is used to control a region and/or area of the PCE 110 that undergoes the phase change (e.g., between the amorphous phase and the crystalline phase).

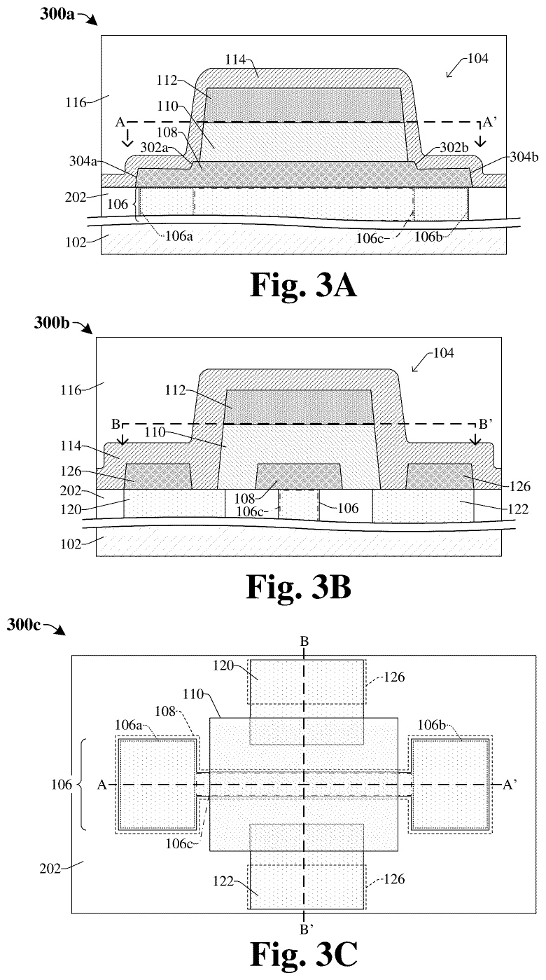

FIGS. 3A-3C illustrate various views of some other embodiments of the integrated chip of FIGS. 2A-2C, where the thermal barrier structure 108 comprises a first pair of opposing sidewalls 302a, 302b vertically above a second pair of opposing sidewalls 304a, 304b. The first pair of opposing sidewalls 302a, 302b are spaced laterally between the second pair of opposing sidewalls 304a, 304b. FIG. 3A illustrates cross-sectional view 300a corresponding to some embodiments of the integrated chip taken along the line A-A′ of a top view 300c of FIG. 3C. FIG. 3B illustrates cross-sectional view 300b corresponding to some embodiments of the integrated chip taken along the line B-B′ of the top view 300c of FIG. 3C.

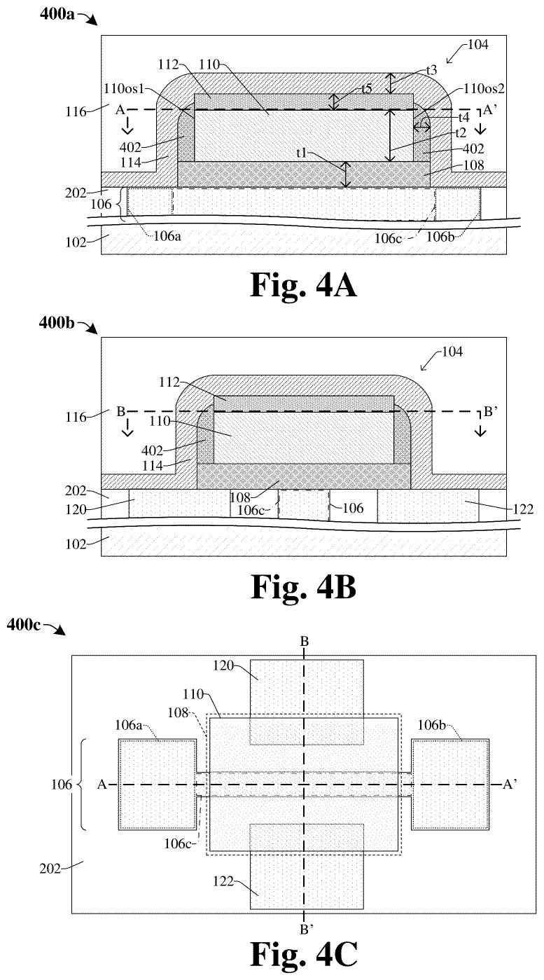

FIGS. 4A-4C illustrate various views of some other embodiments of the integrated chip of FIGS. 2A-2C, where a sidewall spacer structure 402 is disposed along outer sidewalls of the PCE 110. FIG. 4A illustrates cross-sectional view 400a corresponding to some embodiments of the integrated chip taken along the line A-A′ of a top view 400c of FIG. 4C. FIG. 4B illustrates cross-sectional view 400b corresponding to some embodiments of the integrated chip taken along the line B-B′ of the top view 400c of FIG. 4C.

The sidewall spacer structure 402 continuously extends from a top surface of the thermal barrier structure 108, along outer sidewalls 110os1, 110os2 of the PCE 110, to opposing sidewalls of the hard mask 112. In various embodiments, the sidewall spacer structure 402 laterally wraps around an outer perimeter of the PCE 110. The sidewall spacer structure 402 has a fourth thickness t4 that may, for example, be within a range of about 200 angstroms to 600 angstroms, or some other suitable value. Further, the hard mask 112 has a fifth thickness t5 that may, for example, be within a range of about 300 angstroms to about 600 angstroms, or some other suitable value. In some embodiments, the fourth thickness t4 may be less than the first thickness t1, the second thickness t2, and/or the fifth thickness t5. In yet further embodiments, the fourth thickness t4 may be greater than the third thickness t3. Further, the sidewall spacer structure 402 may, for example, be or comprise silicon nitride, silicon carbide, a non-oxygen based dielectric material, another dielectric material, or any combination of the foregoing. In some embodiments, by virtue of the sidewall spacer structure 402 comprising a non-oxygen based dielectric material, oxidation of the PCE 110 during operation of the PCM device 104 is mitigated, thereby increasing an overall performance (e.g., stability and endurance) of the PCM device 104. In some embodiments, the sidewall spacer structure 402 and the thermal barrier structure 108 may comprise a same material (e.g., such as silicon nitride, silicon carbide, a non-oxygen based dielectric material, or some other suitable material). In various embodiments, by virtue of a layout, material, and/or thickness of the sidewall spacer structure 402, the sidewall spacer structure 402 increases isolation between the heater structure 106 and the PCE 110, thereby mitigating damage (e.g., peeling, cracking, etc.) to the PCE 110 during operation and/or fabrication of the PCM device 104 (e.g., due to high heat during switching operations and/or high heat during processing steps). As a result, the sidewall spacer structure 402 increases a stability, an endurance, and an overall performance of the PCM device 104.

In some embodiments, the thermal barrier structure 108 extends past outer sidewalls 110os1, 110os2 of the PCE 110 and is configured to further increase isolation between the PCE 110 and the heater structure 106, thereby further mitigating damage (e.g., peeling, cracking, etc.) to the PCE 110 during operation and/or fabrication of the PCM device 104. As a result, the thermal barrier structure 108 further increases the stability, endurance, and overall performance of the PCM device 104. In various embodiments, as illustrated in the top view 400c of FIG. 4C, the thermal barrier structure 108 and the PCE 110 have a same shape and/or layout, where the thermal barrier structure 108 has a greater area than the PCE 110 when viewed from above. The thermal barrier structure 108 continuously extends laterally outward from an outer perimeter of the PCE 110. In yet further embodiments, it will be appreciated that for ease of illustration the sidewall spacer structure 402 and the capping layer 114 are omitted from the top view 400c of FIG. 4C. In various embodiments, the sidewall spacer structure 402 continuously laterally extends from the outer perimeter of the PCE 110 to the outer perimeter of the thermal barrier structure 108. In yet further embodiments, the thermal barrier structure 108 directly overlies at least portions of the first and second RF structures 120, 122.

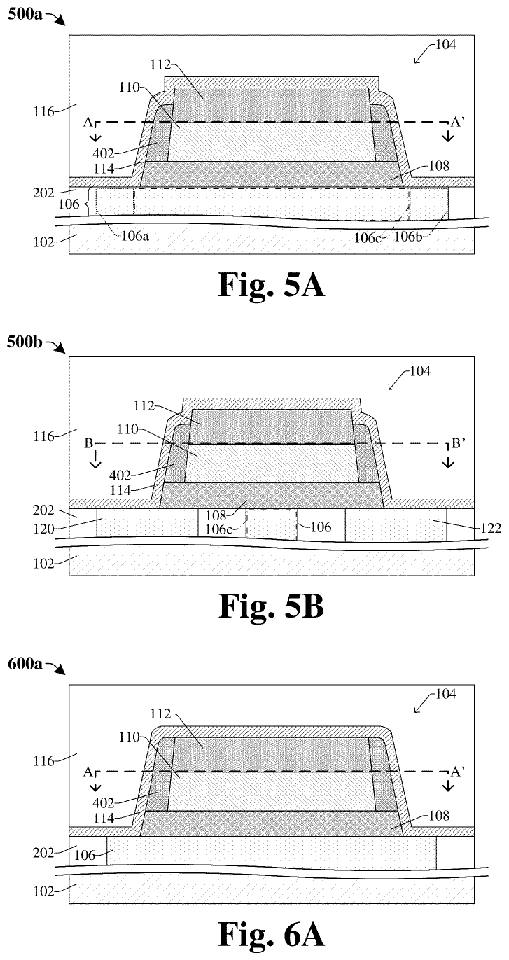

FIGS. 5A and 5B illustrate cross-sectional views 500a and 500b of some other embodiments of the integrated chip of FIGS. 4A-4C, where outer sidewalls of the thermal barrier structure 108, outer sidewalls of the sidewall spacer structure 402, outer sidewalls of the PCE 110, and outer sidewalls of the hard mask 112 are slanted relative to a top surface of the semiconductor substrate 102. FIG. 5A illustrates the cross-sectional view 500a corresponding to some embodiments of the integrated chip taken along the line A-A′ of the top view 400c of FIG. 4C. FIG. 5B illustrates the cross-sectional view 500b corresponding to some embodiments of the integrated chip taken along the line B-B′ of the top view 400c of FIG. 4C.

FIGS. 6A and 6B illustrate cross-sectional views 600a and 600b of some other embodiments of the integrated chip of FIGS. 4A-4C, where a top surface of the sidewall spacer structure 402 is aligned with and/or co-planar with a top surface of the hard mask 112. FIG. 6A illustrates the cross-sectional view 600a corresponding to some embodiments of the integrated chip taken along the line A-A′ of the top view 400c of FIG. 4C. FIG. 6B illustrates the cross-sectional view 600b corresponding to some embodiments of the integrated chip taken along the line B-B′ of the top view 400c of FIG. 4C.

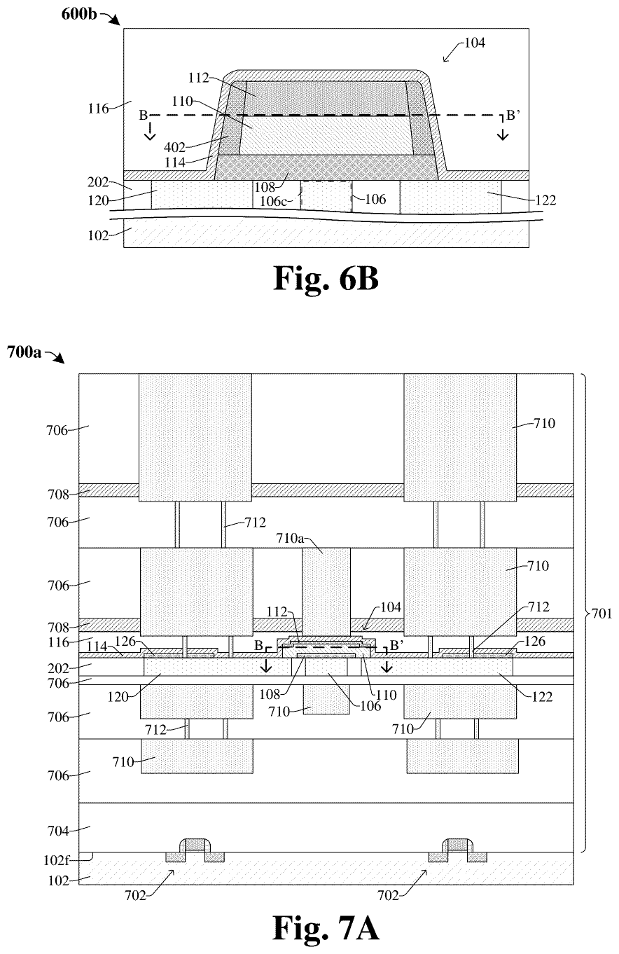

FIGS. 7A and 7B illustrate various views of some embodiments of an integrated chip having a PCM device 104 comprising a thermal barrier structure 108 disposed within an interconnect structure 701. FIG. 7A illustrates a cross-sectional view 700a corresponding to some embodiments of the integrated chip taken along line B-B′ of a top view 700b of FIG. 7B.

The integrated chip comprises an interconnect structure 701 disposed over a semiconductor substrate 102. The semiconductor substrate 102 may be any type of semiconductor body such as, for example, silicon, monocrystalline silicon, silicon germanium, etc., any other type of semiconductor and/or epitaxial layer(s), a silicon-on-insulator (SOI) substrate, some other semiconductor body, or the like. A plurality of semiconductor devices 702 is disposed on and/or within a front-side surface 102f of the semiconductor substrate 102. The semiconductor devices may, for example, each be or comprise a metal oxide semiconductor field effect transistor (MOSFET), a high voltage transistor, a bipolar junction transistor (BJT), an n-channel metal oxide semiconductor (nMOS) transistor, a p-channel metal oxide semiconductor (pMOS) transistor, a gate-all-around FET (GAAFET), a gate-surrounding FET, a multi-bridge channel FET (MBCFET), a nanowire FET, a nanoring FET, a nanosheet field-effect transistor (NSFET), or the like. It will be appreciated that the plurality of semiconductor devices 702 each being configured as another semiconductor device is also within the scope of the disclosure.

The interconnect structure 701 comprises a stack of dielectric layers and a plurality of metallization layers disposed within the stack of dielectric layers. In various embodiments, the plurality of metallization layers comprises a plurality of conductive wires 710 and a plurality of conductive vias 712. Further, the stack of dielectric layers comprises an inter-level dielectric (ILD) layer 704, a plurality of inter-metal dielectric (IMD) layers 706, and a plurality of dielectric protection layers 708. In addition, a PCM device 104 is disposed within the interconnect structure 701 vertically stacked between different metallization layers. In various embodiments, the PCM device 104 may be configured as the PCM device 104 of FIGS. 1A-1B, 2A-2C, or 3A-3C. In some embodiments, the PCM device 104 comprises a heater structure 106, a PCE 110, a thermal barrier structure 108, a hard mask 112, a capping layer 114, a first RF structure 120, and a second RF structure 122.

The conductive wires and vias 710, 712 are configured to facilitate electrical connections between the PCM device 104 and other semiconductor devices and/or structures (e.g., the semiconductor devices 702) disposed within and/or on the semiconductor substrate 102. In some embodiments, one or more conductive vias in the plurality of conductive vias 712 contact the first and second RF structures 120, 122 and the heater structure 106 and are configured to facilitate applying read and/or switching signals to the first and second RF structures 120, 122 and the heater structure 106. The plurality of conductive wires and vias 710, 712 may, for example, be or comprise copper, aluminum, ruthenium, titanium, tantalum, tungsten, some other conductive material, or any combination of the foregoing. The ILD and IMD layers 704, 706 may, for example, be or comprise silicon dioxide, doped silicon dioxide (e.g., carbon doped silicon dioxide), silicon oxynitride, borosilicate glass (BSG), phosphoric silicate glass (PSG), some other low-k dielectric material, or any combination of the foregoing. Further, the dielectric protection layers 708 can be configured as etch stop layer and may, for example, be or comprise silicon nitride, silicon oxynitride, silicon carbide, silicon oxycarbide, some other dielectric material, or the like. In various embodiments, the metallization layers may further comprise an upper conductive structure 710a disposed over the PCE 110 of the PCM device 104. In such embodiments, the upper conductive structure 710a may be configured as a top electrode. In yet further embodiments, the upper conductive structure 710a may be omitted (not shown).

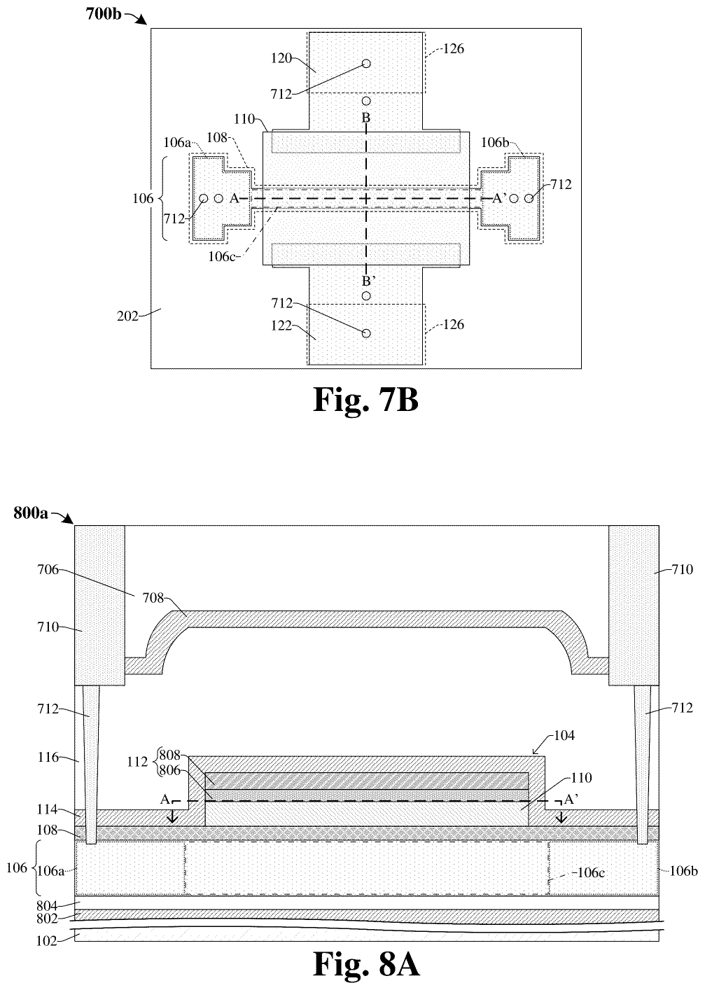

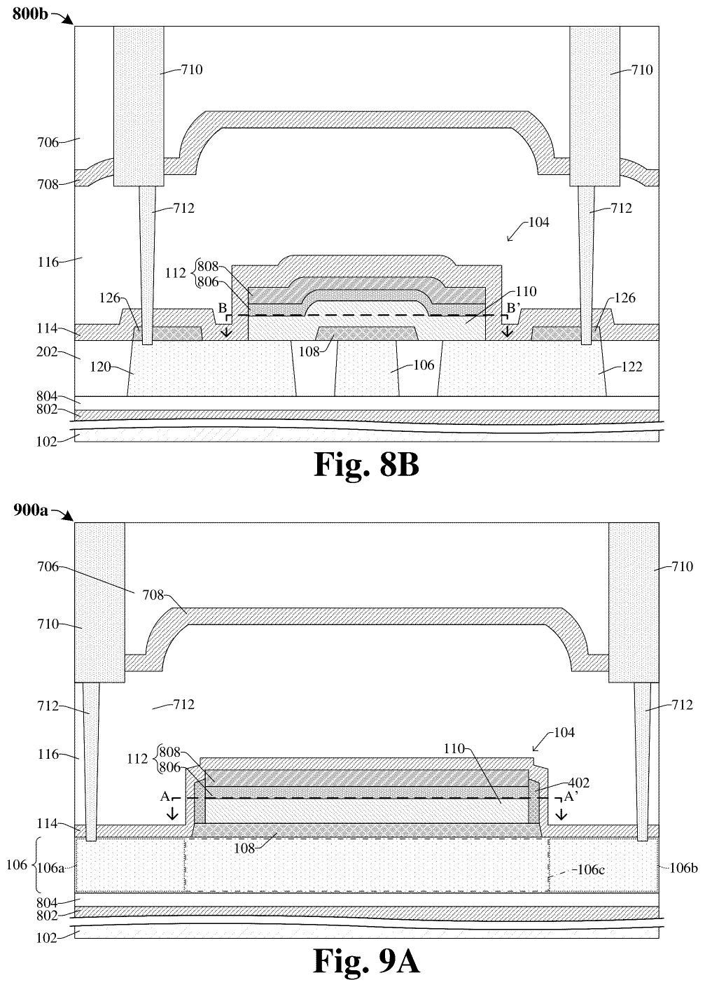

FIGS. 8A and 8B illustrate cross-sectional views 800a and 800b of some embodiments of an integrated chip corresponding to some other embodiments of the integrated chip of FIGS. 7A-7B, where a first dielectric layer 802 and a second dielectric layer 804 are vertically stacked over one another and underlying the heater structure 106. FIG. 8A illustrates the cross-sectional view 800a corresponding to some embodiments of the integrated chip taken along the line A-A′ of the top view 700b of FIG. 7B. FIG. 8B illustrates the cross-sectional view 800b corresponding to some embodiments of the integrated chip taken along the line B-B′ of the top view 700b of FIG. 7B.

Further, the hard mask 112 comprises a first hard mask layer 806 and a second hard mask layer 808. In some embodiments, the first hard mask layer 806 comprises a first dielectric material (e.g., silicon nitride, silicon carbide, etc.) and the second hard mask layer 808 comprises a second dielectric material (e.g., an oxide, silicon dioxide, etc.) different from the first dielectric material. In some embodiments, the second dielectric layer 804 continuously extends along and directly contacts an entirety of a bottom surface of the heater structure 106, an entirety of a bottom surface of the first RF structure 120, and/or an entirety of a bottom surface of the second RF structure 122. In such embodiments, metallization layers in the interconnect structure 701 may be offset the bottom surfaces of the heater structure 106 and the first and second RF structures 120, 122.

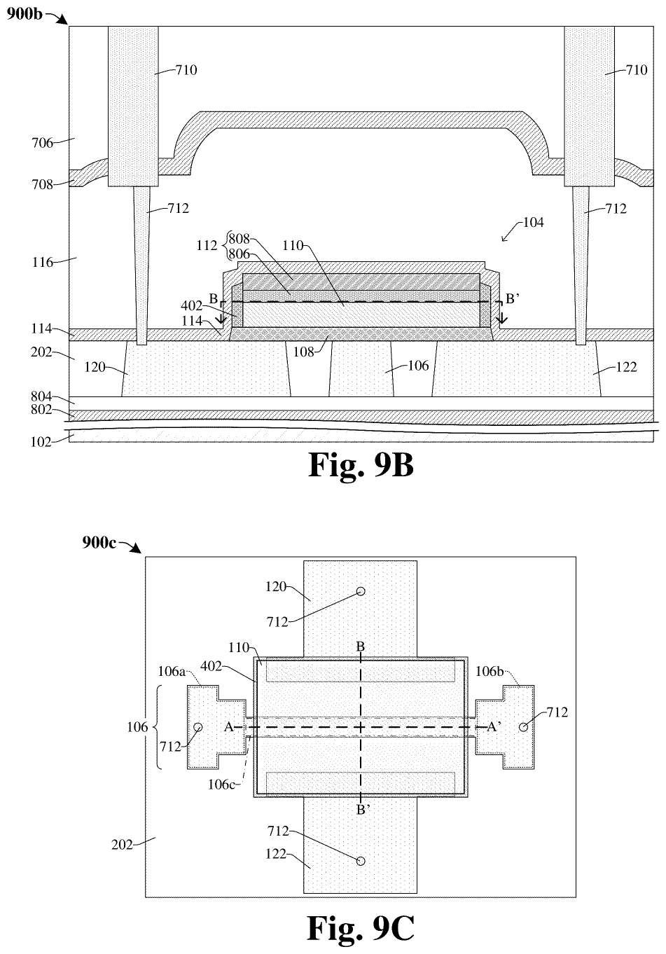

FIGS. 9A-9C illustrate various views of some embodiments of an integrated chip corresponding to some different embodiments of the integrated chip of FIGS. 7A and 7B, where the PCM device 104 comprises a sidewall spacer structure 402 laterally enclosing outer sidewalls of the PCE 110. In various embodiments, the PCM device 104 may be configured as illustrated and/or described in FIGS. 4A-4C, 5A-5B, or 6A-6B. FIG. 9A illustrates cross-sectional view 900a corresponding to some embodiments of the integrated chip taken along the line A-A′ of a top view 900c of FIG. 9C. FIG. 9B illustrates cross-sectional view 900b corresponding to some embodiments of the integrated chip taken along the line B-B′ of the top view 900c of FIG. 9C. It will be appreciated that for ease of illustration the PCE 110 and the sidewall spacer structure 402 are at least partially transparent and the capping layer 114 is omitted in the top view 900c of FIG. 9C.

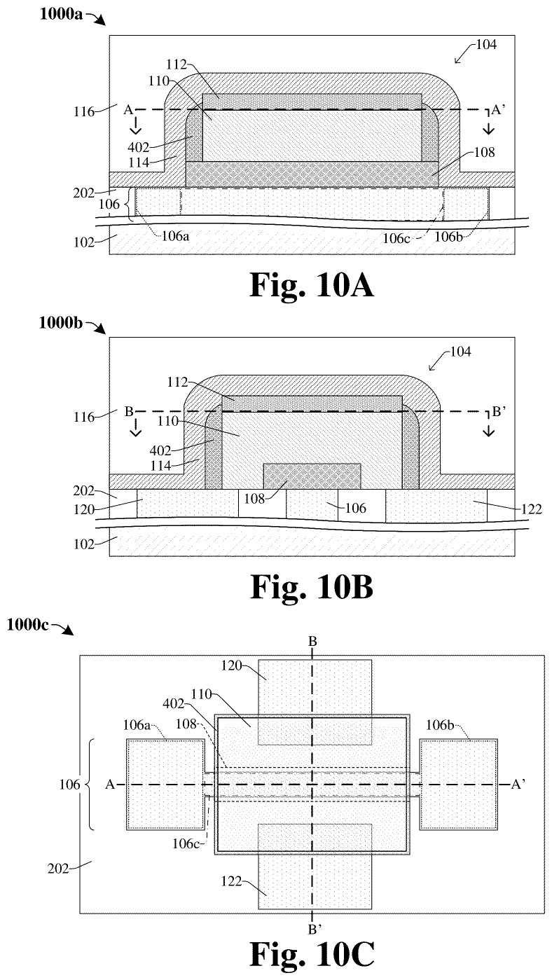

FIGS. 10A-10C illustrate various views of some other embodiments of the integrated chip of FIGS. 4A-4C, where the PCE 110 extends along opposing sidewalls of the thermal barrier structure 108. FIG. 10A illustrates cross-sectional view 1000a corresponding to some embodiments of the integrated chip taken along the line A-A′ of a top view 1000c of FIG. 10C. FIG. 10B illustrates cross-sectional view 1000b corresponding to some embodiments of the integrated chip taken along the line B-B′ of the top view 1000c of FIG. 10C. It will be appreciated that for ease of illustration the capping layer 114 and the upper dielectric layer 116 are omitted from the top view 1000c of FIG. 10C and the PCE 110 and the sidewall spacer structure 402 are at least partially transparent in the top view 1000c of FIG. 10C.

In various embodiments, as illustrated in the cross-sectional view 1000b of FIG. 10B, a bottom surface of the sidewall spacer structure 402 and a bottom surface of the PCE 110 are aligned with a bottom surface of the thermal barrier structure 108. In yet further embodiments, as illustrated in the top view 1000c of FIG. 10C, the thermal barrier structure 108 has a greater width than that of the middle heater segment 106c.

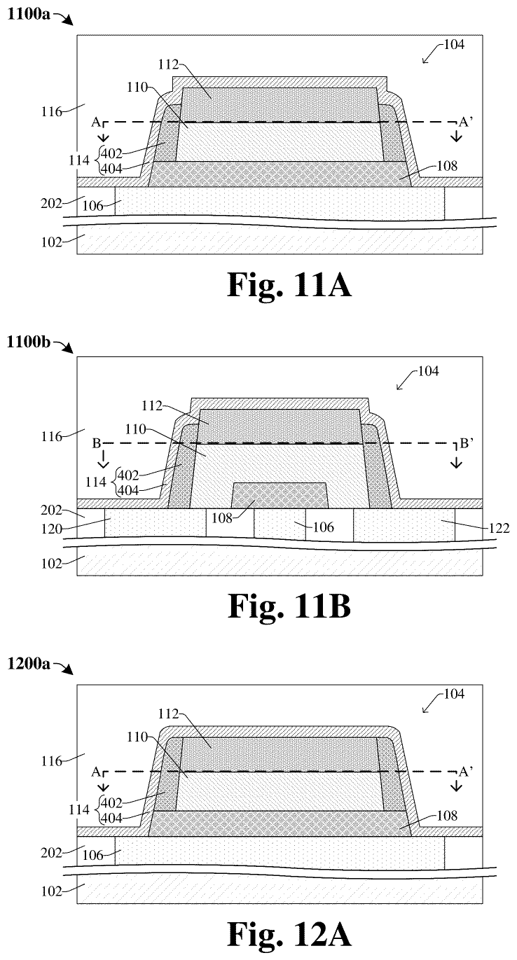

FIGS. 11A and 11B illustrate cross-sectional views 1100a and 1100b of some other embodiments of the integrated chip of FIGS. 10A-10C, where outer sidewalls of the thermal barrier structure 108, outer sidewalls of the sidewall spacer structure 402, outer sidewalls of the PCE 110, and outer sidewalls of the hard mask 112 are slanted relative to a top surface of the semiconductor substrate 102. FIG. 11A illustrates the cross-sectional view 1100a corresponding to some embodiments of the integrated chip taken along the line A-A′ of the top view 1000c of FIG. 10C. FIG. 11B illustrates the cross-sectional view 1100b corresponding to some embodiments of the integrated chip taken along the line B-B′ of the top view 1000c of FIG. 10C.

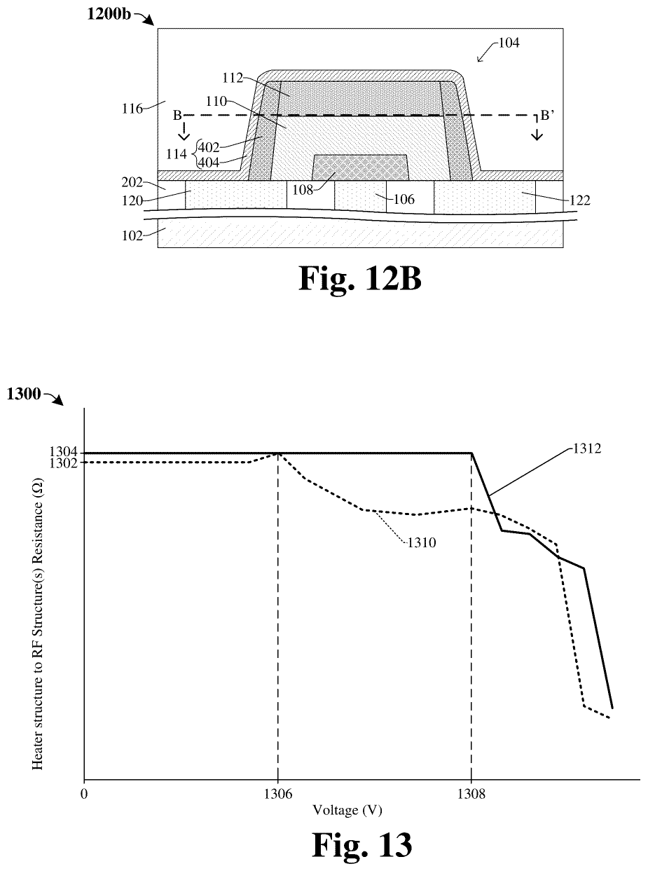

FIGS. 12A and 12B illustrate cross-sectional views 1200a and 1200b of some other embodiments of the integrated chip of FIGS. 10A-10C, where a top surface of the sidewall spacer structure 402 is aligned with and/or co-planar with a top surface of the hard mask 112. FIG. 12A illustrates the cross-sectional view 1200a corresponding to some embodiments of the integrated chip taken along the line A-A′ of the top view 1000c of FIG. 10C. FIG. 12B illustrates the cross-sectional view 1200b corresponding to some embodiments of the integrated chip taken along the line B-B′ of the top view 1000c of FIG. 10C.

FIG. 13 illustrates a graph 1300 comprising resistance curves 1310, 1312 of some different embodiments of a PCM device including a thermal barrier structure. For example, the resistance curve 1312 may corresponding to operation of the PCM device as previously illustrated and/or described in FIGS. 1A-1B. These resistance curves 1310, 1312 reflect varying switching operations being carried out at different voltages on the PCM device. In the switching operations, for example, a voltage (e.g., a switching signal) is applied to the first and/or second outer heater segments 106a-b to generate a heater current across the middle heater segment 106c.

In various embodiments, a first resistance curve 1310 represents some embodiments of operating conditions of a second PCM device that comprises a PCE having outer sidewalls aligned with outer sidewalls of the thermal barrier structure (e.g., a length of thermal barrier structure may be equal to or less than a length of the PCE). The first resistance curve 1310 depicts a resistance between the heater structure of the second PCM device and RF structures of the second PCM device. In some embodiments, the resistance between the heater structure and RF structures of the second PCM device goes below a first resistance value 1302 after voltage(s) greater than a first voltage 1306 is/are applied to the heater structure of the second PCM device. Because the thermal barrier structure of the second PCM device does not sufficiently increases isolation between the heater structure and the RF structures, the first voltage 1306 is relatively small, such that breakdown of the second PCM device may occur at relatively low voltages (e.g., at about 7 volts).

In some embodiments, a second resistance curved 1312 represents some embodiments of operating conditions of a PCM device in accordance with the present disclosure, in which outer sidewalls of the PCE are spaced laterally between outer sidewalls of the thermal barrier structure. In some embodiments, the second resistance curved 1312 depicts a resistance between the heater structure (e.g., 106 of FIGS. 1A-1B) and the first and/or second RF structures (e.g., 120, 122 of FIG. 1B). In some embodiments, the resistance between the heater structure and the first and/or second RF structures goes below a second resistance value 1304 after voltage(s) greater than a second voltage 1308 is/are applied to the heater structure (e.g., 106 of FIGS. 1A-1B) of the PCM device. Because the thermal barrier structure (e.g., 108 of FIGS. 1A-1B) increases isolation between the heater structure and the first and/or second RF structures, the second voltage 1308 is relatively high, such that breakdown of the PCM device may occur at relatively high voltages (e.g., at about 14 volts or more). As can be seen by a comparison of curves 1310, 1312, the layout, material, and/or thickness of the thermal barrier structure 108, as illustrated and/or described in embodiments in accordance with the present disclosure, increases isolation between conductive structures of the PCM device 104 and/or between the heater structure 106 and the PCE 110. As a result, a breakdown voltage, endurance, and stability of the PCM device 104 are increased.

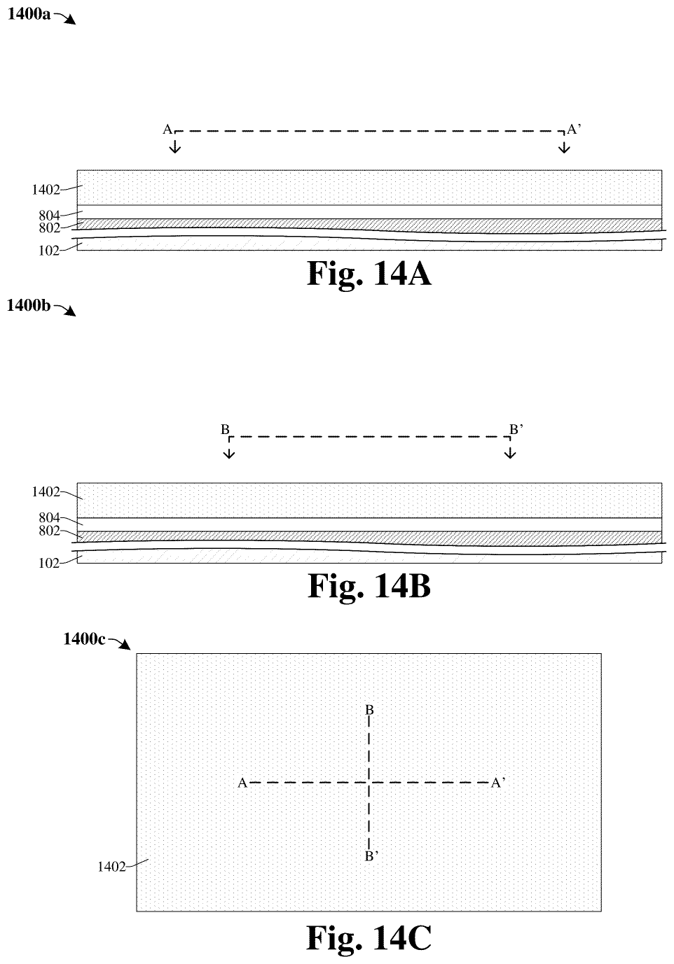

FIGS. 14A-14C through 23A-23C illustrate a series of various views of some embodiments of a method for forming an integrated chip comprising a PCM device having a thermal barrier structure configured to increase a performance of the PCM device. Figures with a suffix of “A” illustrate a cross-sectional view of the integrated chip during various formation processes taken along the line A-A′ of figures with a suffix of “C”. Figures with a suffix of “B” illustrate a cross-sectional view taken along the line B-B′ of figures with a suffix of “C”. Figures with a suffix of “C” illustrate a top view of the integrated chip during various formation processes. Although the various views shown in FIGS. 14A-14C through 23A-23C are described with reference to a method of forming the integrated chip, it will be appreciated that the structures shown in FIGS. 14A-14C through 23A-23C are not limited to the method of formation but rather may stand alone separate of the method.

As shown in cross-sectional views 1400a-b and top view 1400c of FIGS. 14A-14C, a semiconductor substrate 102 is provided and a first dielectric layer 802, a second dielectric layer 804, and a conductive layer 1402 are formed over the semiconductor substrate 102. In some embodiments, the first dielectric layer 802 and the second dielectric layer 804 may each be formed over the semiconductor substrate 102 by chemical vapor deposition (CVD), physical vapor deposition (PVD), atomic layer deposition (ALD), or some other suitable deposition or growth process. The conductive layer 1402 may, for example, be formed by CVD, PVD, ALD, electroplating, electroless plating, or some other suitable growth or deposition process. The conductive layer 1402 may, for example, be or comprise tungsten, titanium, titanium nitride, molybdenum, some other conductive material, or any combination of the foregoing.

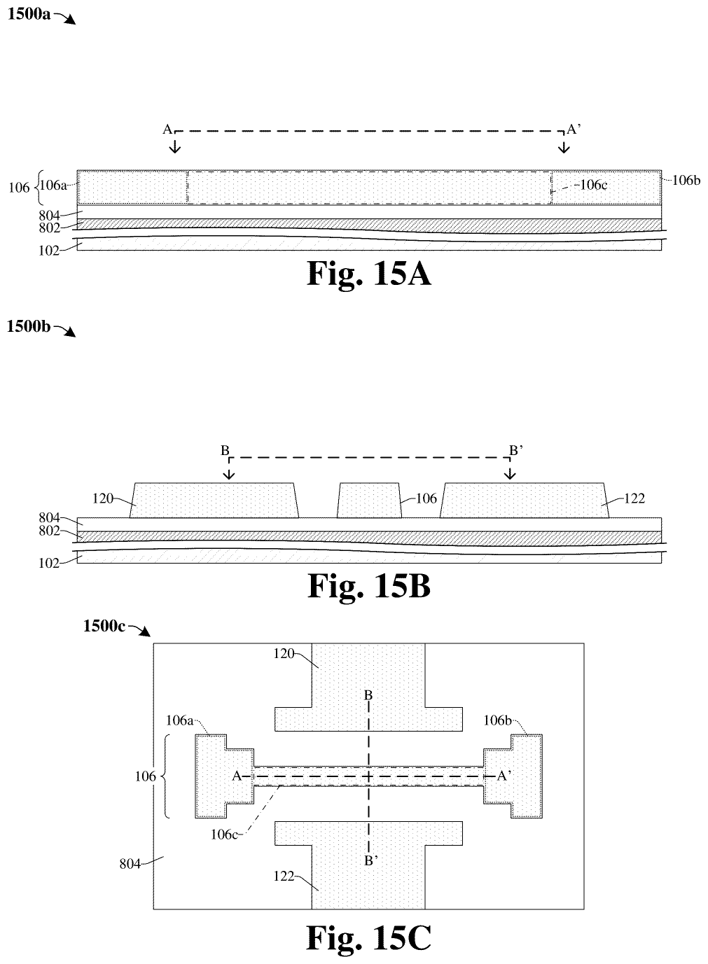

As shown in cross-sectional views 1500a-b and top view 1500c of FIGS. 15A-15C, an etching process is performed on the conductive layer (1402 of FIGS. 14A-14C) to define a first radio frequency (RF) structure 120, a second RF structure 122, and a heater structure 106. In various embodiments, the heater structure 106 is formed such that the heater structure 106 comprises a first outer heater segment 106a, a second outer heater segment 106b, and a middle heater segment 106c. In some embodiments, the etching process comprises: forming a patterned mask (not shown) over the conductive layer (1402 of FIGS. 14A-14C); exposing the conductive layer (1402 of FIGS. 14A-14C) to one more etchants with the patterned mask in place, thereby removing unmasked regions of the conductive layer (1402 of FIGS. 14A-14C); and performing a removal process to remove the patterned mask. In some embodiments, the etching process comprises a wet etch, a dry etch, or a combination of the foregoing. In yet further embodiments, the heater structure 106 is formed such that the first and second outer heater segments 106a, 106b each have one or more widths greater than a width of the middle heater segment 106c. In some embodiments, the first RF structure 120, the second RF structure 122, and the heater structure 106 are formed concurrently with one another.

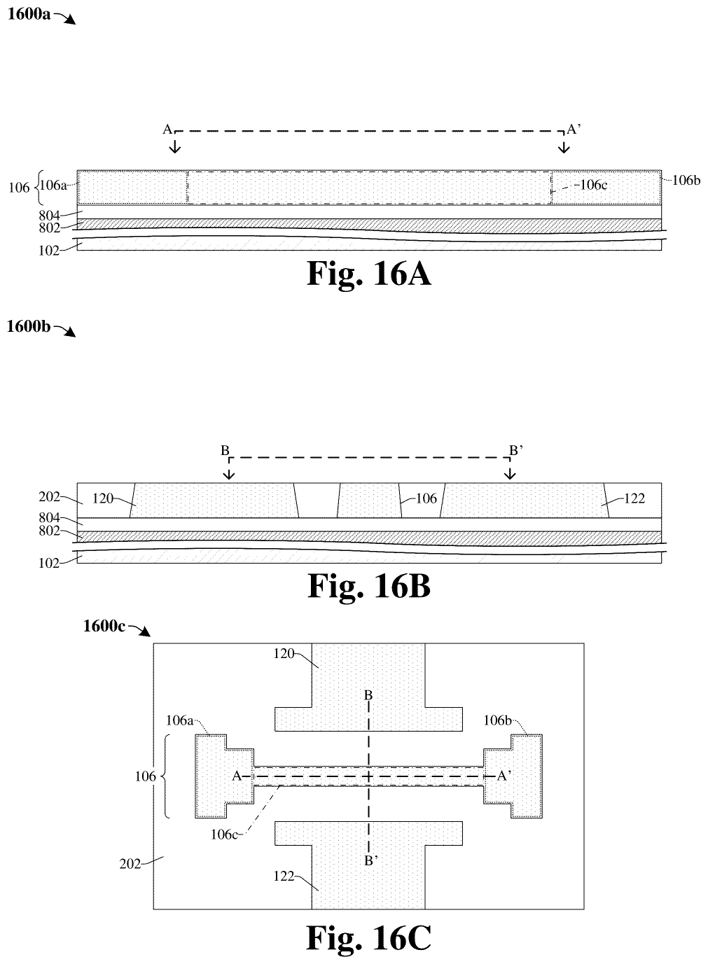

As shown in cross-sectional views 1600a-b and top view 1600c of FIGS. 16A-16C, a lower dielectric layer 202 is formed over the second dielectric layer 804. The lower dielectric layer 202 may, for example, be formed by CVD, PVD, ALD, or some other suitable deposition or growth process. In yet further embodiments, after depositing the lower dielectric layer 202 a planarization process (e.g., a chemical mechanical planarization (CMP) process, an etch process, etc.) may be performed on the lower dielectric layer 202 such that a top surface of the lower dielectric layer 202 is co-planar with a top surface of the heater structure 106, a top surface of the first RF structure 120, and/or a top surface of the second RF structure 122.

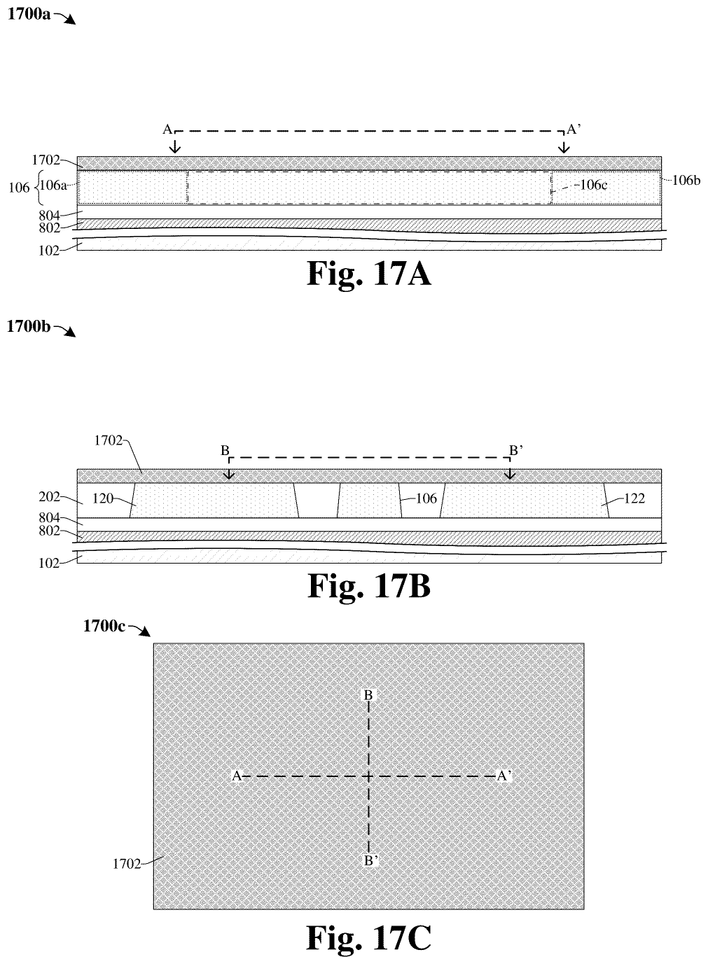

As shown in cross-sectional views 1700a-b and top view 1700c of FIGS. 17A-17C, a thermal barrier layer 1702 is formed over the heater structure 106 and the first and second RF structures 120, 122. The thermal barrier layer 1702 may, for example, be or comprise silicon nitride, silicon carbide, aluminum nitride, a non-oxygen based dielectric material, a high-k dielectric material, some other suitable material, or any combination of the foregoing. The thermal barrier layer 1702 may, for example, be formed by CVD, PVD, ALD, or some other suitable deposition or growth process. In some embodiments, the thermal barrier layer 1702 may be formed to a thickness within a range of about 300 angstroms to about 600 angstroms, or to some other suitable thickness value.

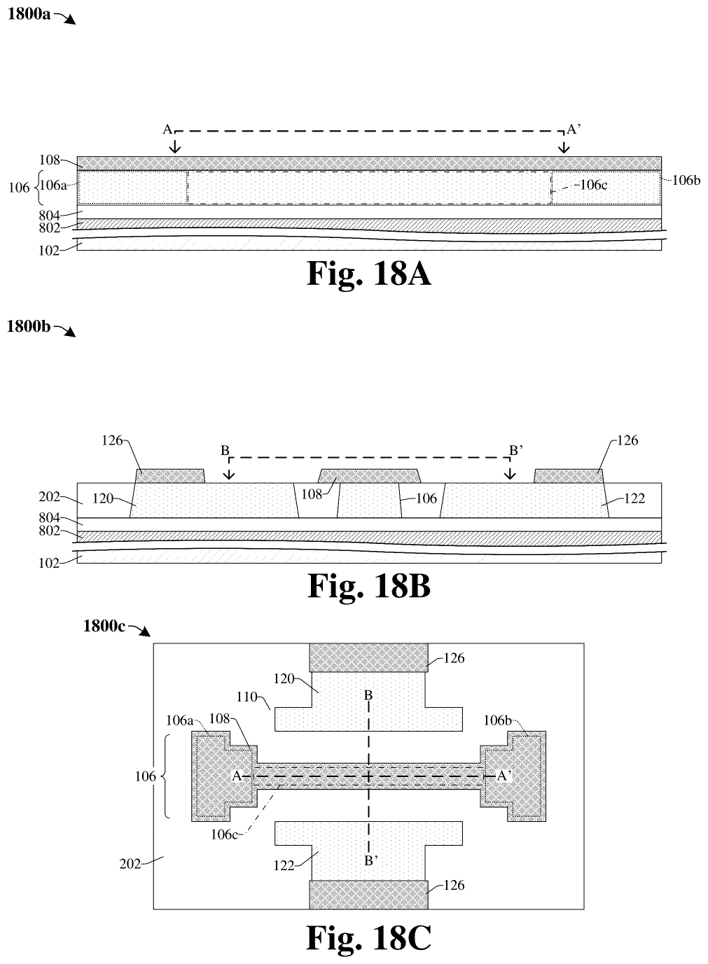

As shown in cross-sectional views 1800a-b and top view 1800c of FIGS. 18A-18C, an etching process is performed on the thermal barrier layer (1702 of FIGS. 17A-17C) to define a thermal barrier structure 108 and an etch stop layer 126. In some embodiments, the thermal barrier structure 108 is formed such that the heater structure 106 and the thermal barrier structure 108 have a same shape and/or layout. In such embodiments, the thermal barrier structure 108 continuously extends laterally outward from an outer perimeter of the heater structure 106, where the thermal barrier structure 108 has a greater area than the heater structure 106 when viewed from above. In some embodiments, the etching process comprises: forming a patterned mask (not shown) over the thermal barrier layer (1702 of FIGS. 17A-17C); exposing the thermal barrier layer (1702 of FIGS. 17A-17C) to one or more etchants with the patterned mask in place, thereby removing unmasked regions of the thermal barrier layer (1702 of FIGS. 17A-17C); and performing a removal process to remove the patterned mask. In various embodiments, the etching process comprises a wet etch, a dry etch, or a combination of the foregoing. In some embodiments, the thermal barrier structure 108 and the etch stop layer 126 are formed concurrently with one another.

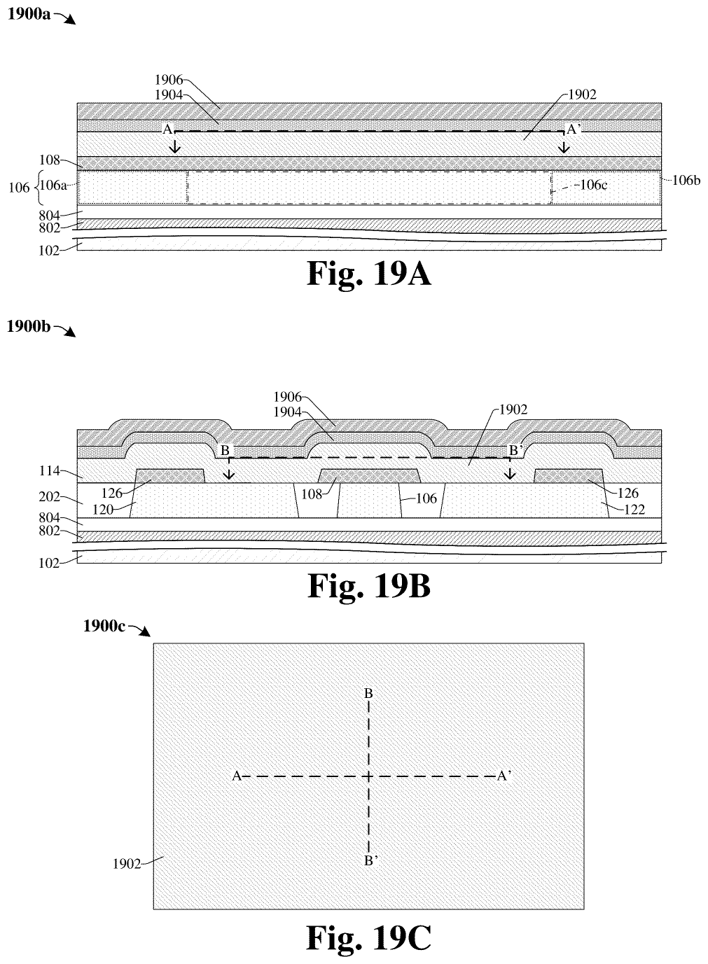

As shown in cross-sectional views 1900a-b and top view 1900c of FIGS. 19A-19C, a stack of layers 1902-1906 is formed over the heater structure 106. In some embodiments, the stack of layers 1902-1906 comprises a PCE layer 1902, a first mask layer 1904, and a second mask layer 1906. In various embodiments, the PCE layer 1902, the first mask layer 1904, and the second mask layer 1906 may each be formed by an individual deposition process such as a CVD process, a PVD process, and ALD process, or some other suitable deposition or growth process. The PCE layer 1902 may, for example, be or comprise a PCM such as one or more chalcogenide material(s) that comprise at least one chalcogen ion (e.g., a chemical element in column VI of the periodic table), germanium antimony telluride (GST), another suitable phase-change alloy, or some other suitable material. Further, the PCE layer 1902 may, for example, be formed to a thickness within a range of about 500 angstroms to about 1,000 angstroms, or some other suitable thickness value.

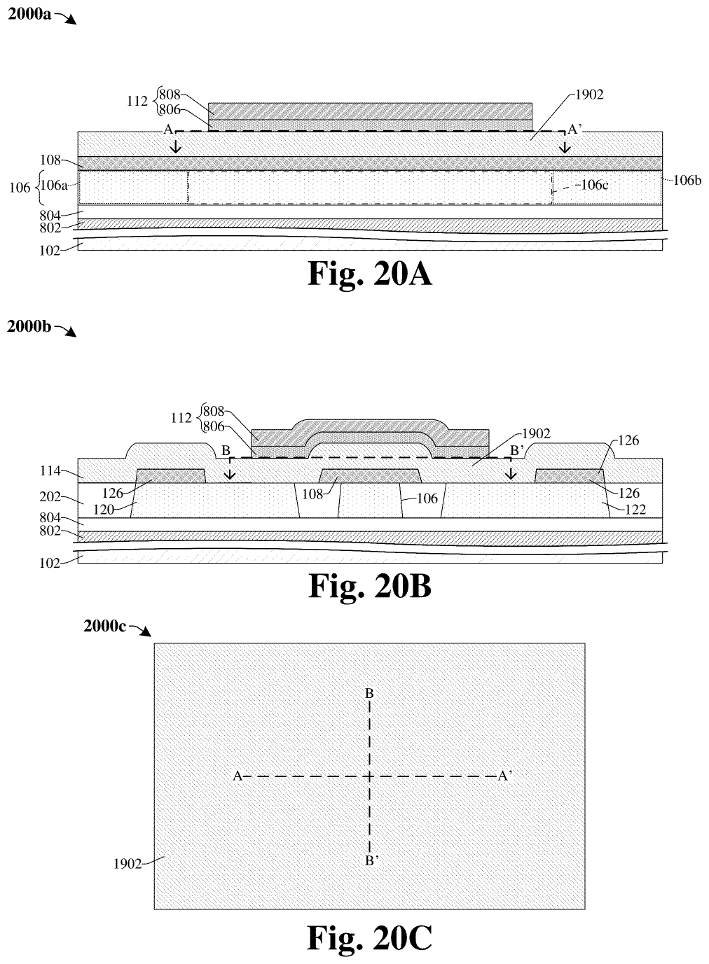

As shown in cross-sectional views 2000a-b and top view 2000c of FIGS. 20A-20C, a first patterning process is performed on the first and second mask layers (1904 and 1906 of FIGS. 19A-C) to define a hard mask 112 comprising a first hard mask layer 806 and a second hard mask layer 808. In some embodiments, the first patterning process comprises: forming a first mask (not shown) over the first and second mask layers (1904 and 1906 of FIGS. 19A-C); exposing the first and second mask layers (1904 and 1906 of FIGS. 19A-C) to one or more etchants with the first mask in place, thereby removing unmasked regions of the first and second mask layers (1904 and 1906 of FIGS. 19A-C); and performing a removal process to remove the first mask. In various embodiments, the first patterning process comprises a wet etch, a dry etch, or a combination of the foregoing.

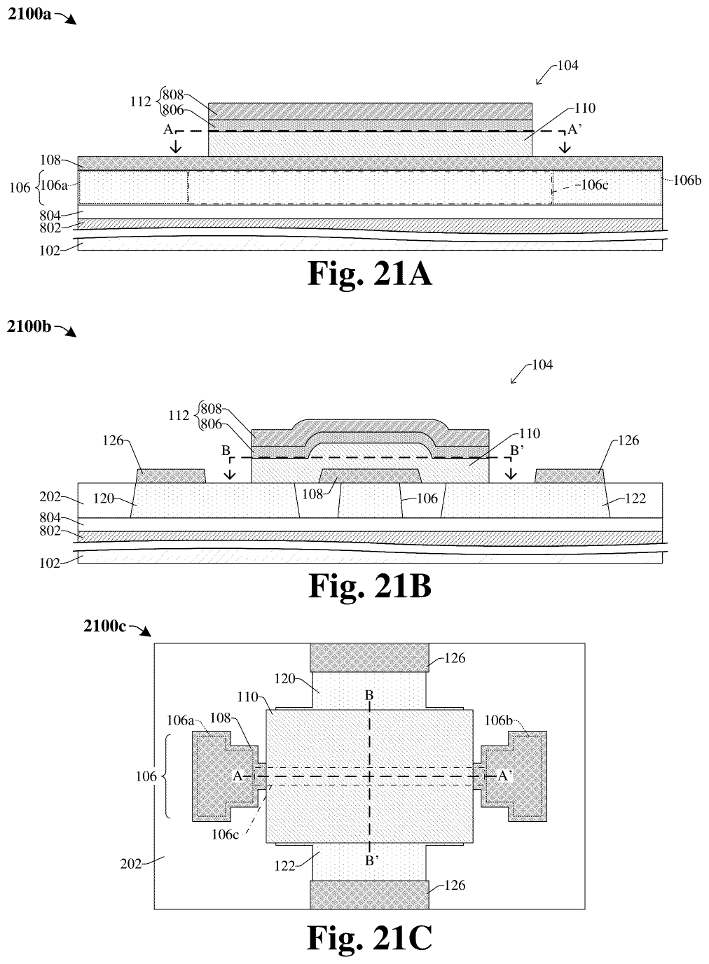

As shown in cross-sectional views 2100a-b and top view 2100c of FIGS. 21A-21C, a second patterning process is performed on the PCE layer (1902 of FIGS. 20A-C) to define a PCE 110 and a PCM device 104 over the heater structure 106. In some embodiments, the second patterning process comprises exposing the PCE layer (1902 of FIGS. 20A-C) to one or more etchants with the hard mask 112 in place, thereby removing unmasked regions of the PCE layer (1902 of FIGS. 20A-C). In various embodiments, the second patterning process comprises a wet etch, a dry etch, or a combination of the foregoing. In yet further embodiments, the second patterning process is different from the first patterning process of FIGS. 20A-20C.

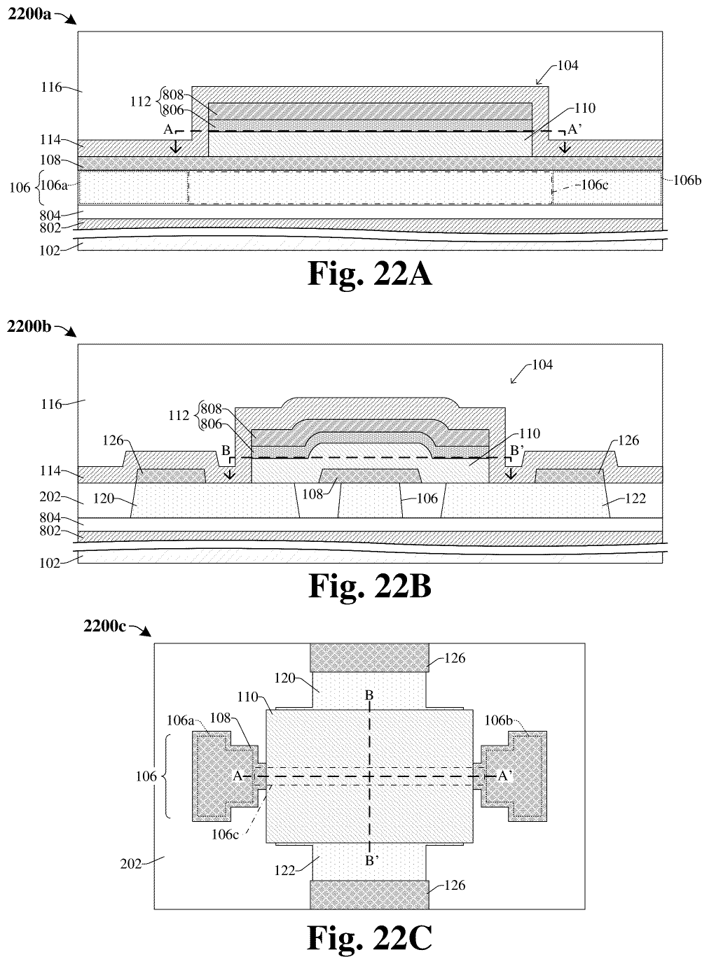

As shown in cross-sectional views 2200a-b and top view 2200c of FIGS. 22A-22C, a capping layer 114 and an upper dielectric layer 116 are formed over the PCM device 104. In some embodiments, the capping layer 114 and the upper dielectric layer 116 may, for example, each be formed by a CVD process, a PVD process, an ALD process, or some other suitable growth or deposition process. It will be appreciated that the capping layer 114 and the upper dielectric layer 116 are omitted from the top view 2200c of FIG. 22C for ease of illustration. In various embodiments, the capping layer 114 may be formed to a thickness within a range of about 100 angstroms to about 400 angstroms, or some other suitable thickness value.

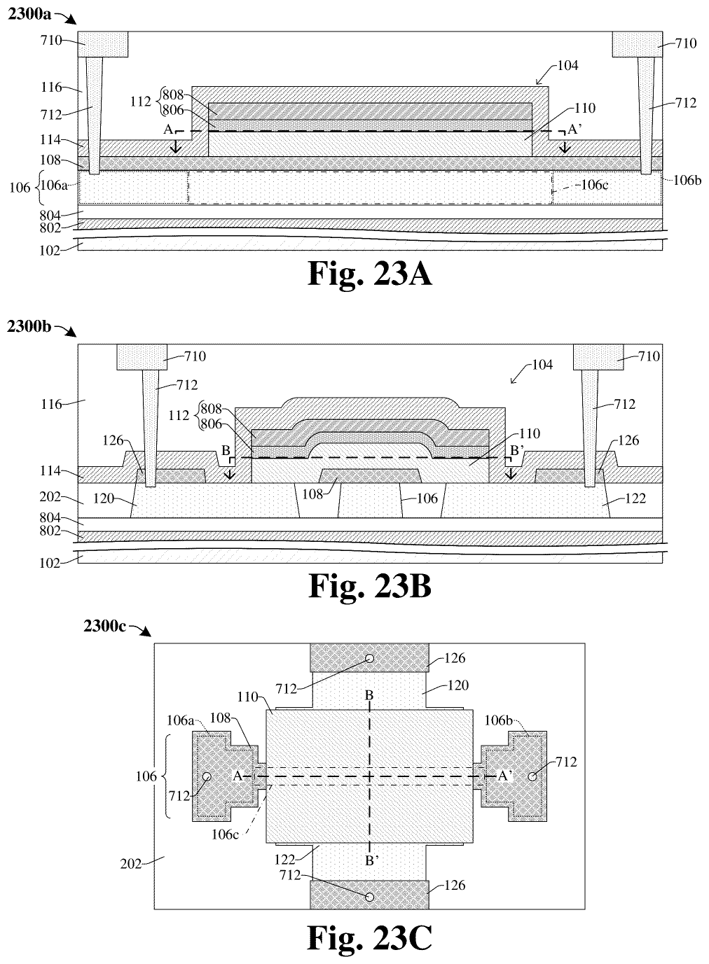

As shown in cross-sectional views 2300a-b and top view 2300c of FIGS. 23A-23C, a plurality of conductive vias 712 and a plurality of conductive wires 710 are formed over the PCM device 104. It will be appreciated that the capping layer 114 and the upper dielectric layer 116 are omitted from the top view 2300c of FIG. 23C for ease of illustration. The conductive wires and vias 710, 712 may, for example, be formed by one or more deposition process(es), one or more patterning process(es), one or more planarization process(es), some other suitable fabrication process(es), or any combination of the foregoing. In some embodiments, a process for forming the conductive wires and vias 710, 712 comprises: patterning the upper dielectric layer 116, the capping layer 114, the thermal barrier structure 108, and/or the etch stop layer 126 to form a plurality of metallization openings over the heater structure 106 and the first and second RF structures 120, 122; filling the plurality of metallization openings with a conductive material (e.g., copper, aluminum, titanium nitride, tantalum nitride, ruthenium, another meal material, or any combination of the foregoing); and performing a planarization process (e.g., a CMP process, an etching process, etc.) into the conductive material.

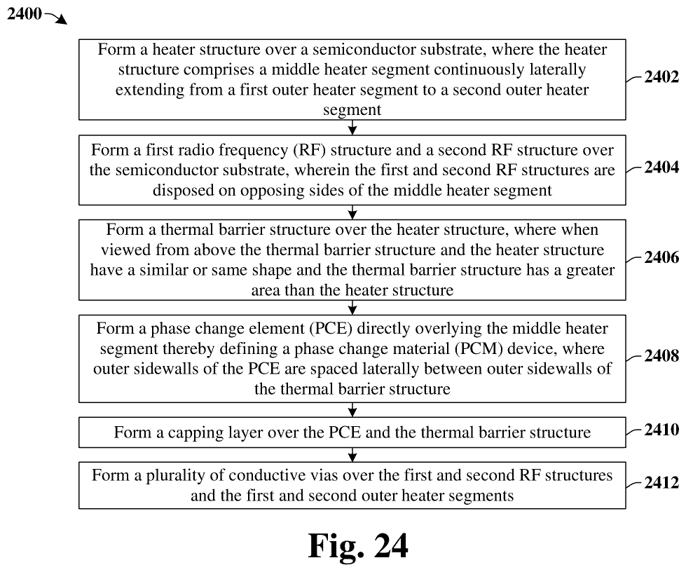

FIG. 24 illustrates a flow diagram of some embodiments of a method 2400 for forming an integrated chip comprising a PCM device having a thermal barrier structure configured to increase a performance of the PCM device. Although the method 2400 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2402, a heater structure is formed over a semiconductor substrate. The heater structure comprises a middle heater segment continuously laterally extending from a first outer heater segment to a second outer heater segment. FIGS. 14A-14C through 15A-15C illustrate various views corresponding to some embodiments of act 2402.

At act 2404, a first radio frequency (RF) structure and a second RF structure are formed over the semiconductor substrate, where the first and second RF structures are disposed on opposing sides of the middle heater segment. FIGS. 14A-14C through 15A-15C illustrate various views corresponding to some embodiments of act 2404.

At act 2406, a thermal barrier structure is formed over the heater structure. When viewed from above the thermal barrier structure and the heater structure have a similar or same shape and the thermal barrier structure has a greater area than the heater structure. FIGS. 17A-17C through 18A-18C illustrate various views corresponding to some embodiments of act 2406.

At act 2408, a phase change element (PCE) is formed directly overlying the middle heater segment thereby defining a PCM device, where outer sidewalls of the PCE are spaced laterally between outer sidewalls of the thermal barrier structure. FIGS. 19A-19C through 21A-21C illustrate various views corresponding to some embodiments of act 2408.

At act 2410, a capping layer is formed over the PCE and the thermal barrier structure. FIGS. 22A-22C illustrate various views corresponding to some embodiments of act 2410.

At act 2412, a plurality of conductive vias is formed over the first and second RF structures and the first and second outer heater segments. FIGS. 23A-C illustrate various views corresponding to some embodiments of act 2412.

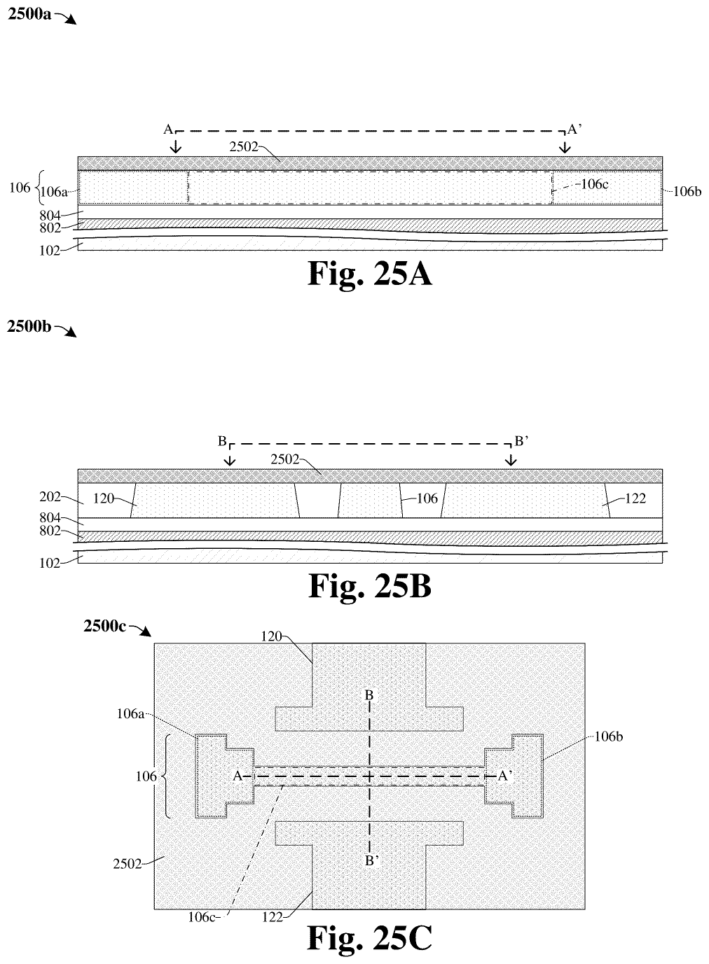

FIGS. 25A-25C through 31A-31C illustrate a series of various views of some embodiments of a method for forming an integrated chip comprising a PCM device having a thermal barrier structure and a sidewall spacer structure configured to increase a performance of the PCM device. Figures with a suffix of “A” illustrate a cross-sectional view of the integrated chip during various formation processes taken along the line A-A′ of figures with a suffix of “C”. Figures with a suffix of “B” illustrate a cross-sectional view taken along the line B-B′ of figures with a suffix of “C”. Figures with a suffix of “C” illustrate a top view of the integrated chip during various formation processes. Although the various views shown in FIGS. 25A-25C through 31A-31C are described with reference to a method of forming the integrated chip, it will be appreciated that the structures shown in FIGS. 25A-25C through 31A-31C are not limited to the method of formation but rather may stand alone separate of the method.

As shown in cross-sectional views 2500a-b and top view 2500c of FIGS. 25A-25C, a semiconductor substrate 102 is provided and a first dielectric layer 802, a second dielectric layer 804, a heater structure 106, a first RF structure 120, a second RF structure 122, and a lower dielectric layer 202 are formed over the semiconductor substrate 102. In various embodiments, the first and second dielectric layers 802, 804, the heater structure 106, the first and second RF structures 120, 122, and the lower dielectric layer 202 are, for example, formed as illustrated and/or described in FIGS. 14A-14C through 16A-16C. Further, a thermal barrier layer 2502 is formed over the heater structure 106 and the first and second RF structures 120, 122. The thermal barrier layer 2502 may, for example, be or comprise silicon nitride, silicon carbide, aluminum nitride, a non-oxygen based dielectric material, a high-k dielectric material, some other suitable material, or any combination of the foregoing. The thermal barrier layer 2502 may, for example, be formed by CVD, PVD, ALD, or some other suitable deposition or growth process. In some embodiments, the thermal barrier layer 2502 may be formed to a thickness within a range of about 300 angstroms to about 600 angstroms, or to some other suitable thickness value. It will be appreciated that for ease of illustration the thermal barrier layer 2502 is partially transparent in the top view 2500c of FIG. 25C.

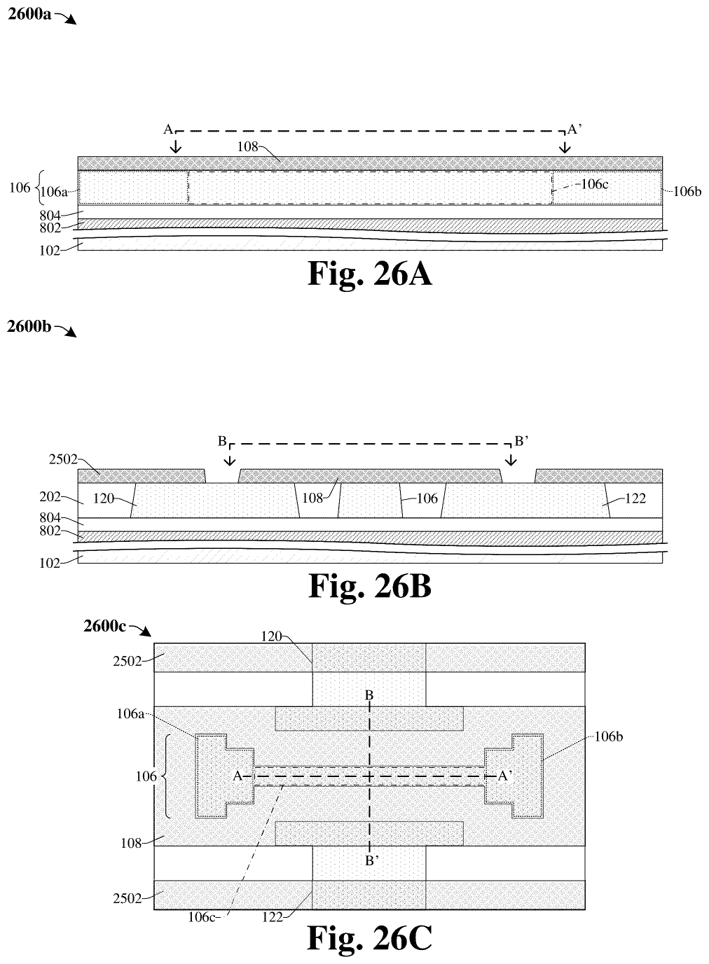

As shown in cross-sectional views 2600a-b and top view 2600c of FIGS. 26A-26C, an etching process is performed on the thermal barrier layer 2502 to define a thermal barrier structure 108 over the heater structure 106. In some embodiments, the etching process comprises: forming a patterned mask (not shown) over the thermal barrier layer 2502; exposing the thermal barrier layer 2502 to one or more etchants with the patterned mask in place, thereby removing unmasked regions of the thermal barrier layer 2502; and performing a removal process to remove the patterned mask. In various embodiments, the etching process comprises a wet etch, a dry etch, or a combination of the foregoing. It will be appreciated that for ease of illustration the thermal barrier layer 2502 and the thermal barrier structure 108 are partially transparent in the top view 2600c of FIG. 26C.

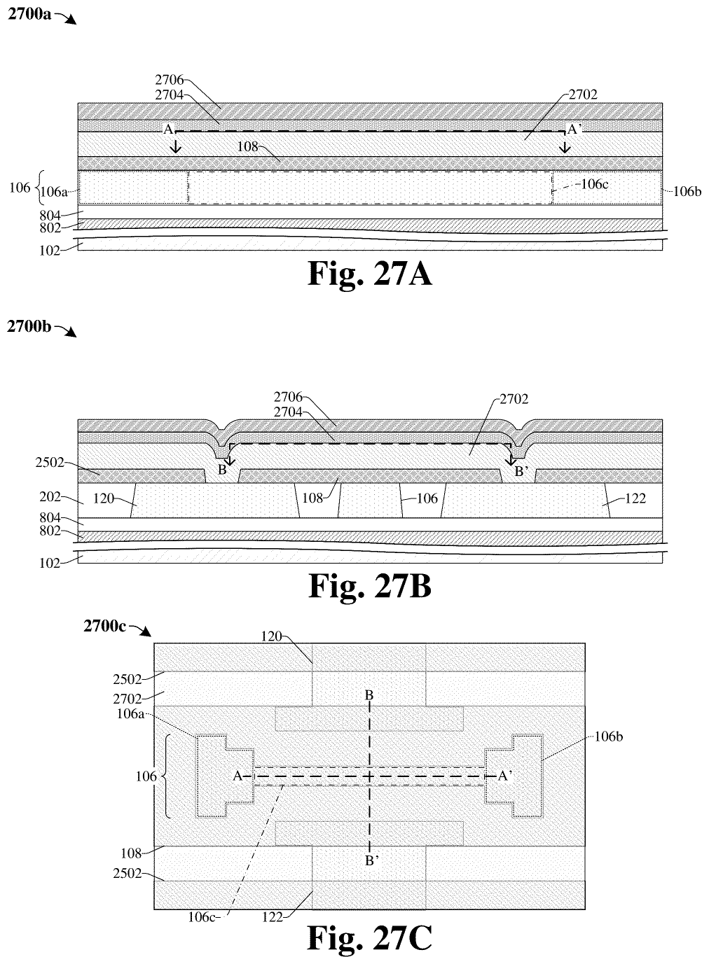

As shown in cross-sectional views 2700a-b and top view 2700c of FIGS. 27A-27C, a stack of layers 2702-2706 is formed over the heater structure 106. In some embodiments, the stack of layers 2702-2706 comprises a PCE layer 2702, a first mask layer 2704, and a second mask layer 2706. In various embodiments, the PCE layer 2702, the first mask layer 2704, and the second mask layer 2706 may each be formed by an individual deposition process such as a CVD process, a PVD process, and ALD process, or some other suitable deposition or growth process. The PCE layer 2702 may, for example, be or comprise a PCM such as one or more chalcogenide material(s) that comprise at least one chalcogen ion (e.g., a chemical element in column VI of the periodic table), germanium antimony telluride (GST), another suitable phase-change alloy, or some other suitable material. Further, the PCE layer 2702 may, for example, be formed to a thickness within a range of about 500 angstroms to about 1,000 angstroms, or some other suitable thickness value. It will be appreciated that for ease of illustration the thermal barrier layer 2502, the thermal barrier structure 108, and the PCE layer 2702 are partially transparent in the top view 2700c of FIG. 27C.

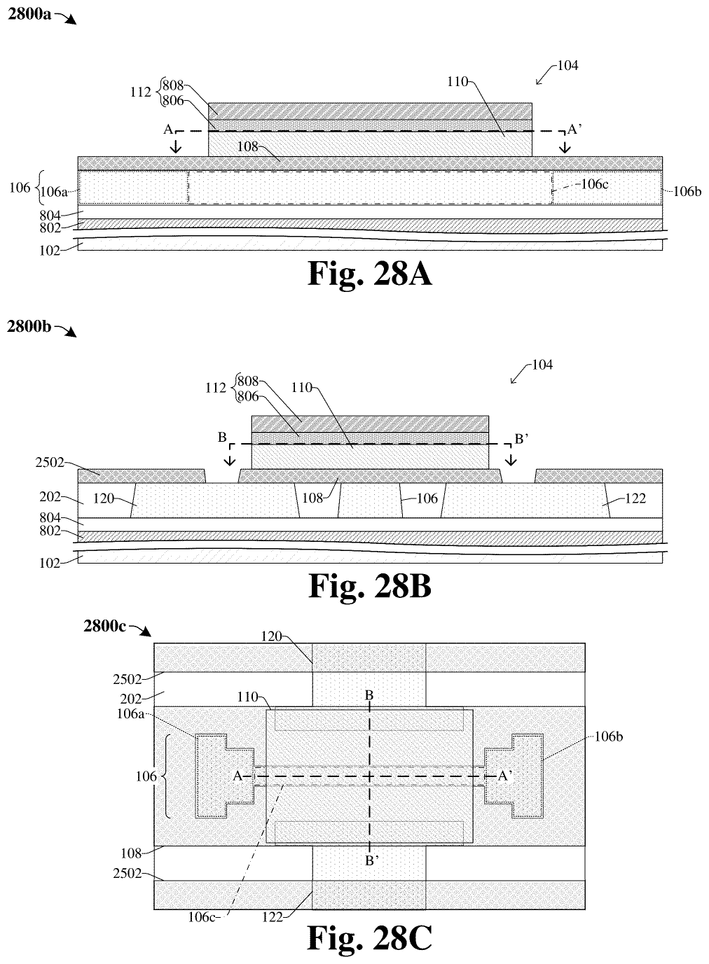

As shown in cross-sectional views 2800a-b and top view 2800c of FIGS. 28A-28C, a first patterning process is performed on the stack of layers (2702-2706 of FIGS. 27A-27C) to define a PCM device 104, a hard mask 112 comprising a first hard mask layer 806 and a second hard mask layer 808, and a PCE 110. In some embodiments, the first patterning process comprises: forming a first mask (not shown) over the stack of layers (2702-2706 of FIGS. 27A-27C); exposing the stack of layers (2702-2706 of FIGS. 27A-27C) to one or more etchants with the first mask in place, thereby removing unmasked regions of the stack of layers (2702-2706 of FIGS. 27A-27C); and performing a removal process to remove the first mask. In various embodiments, the first patterning process comprises a wet etch, a dry etch, or a combination of the foregoing. It will be appreciated that for ease of illustration the thermal barrier layer 2502, the thermal barrier structure 108, and the PCE 110 are partially transparent in the top view 2800c of FIG. 28C.

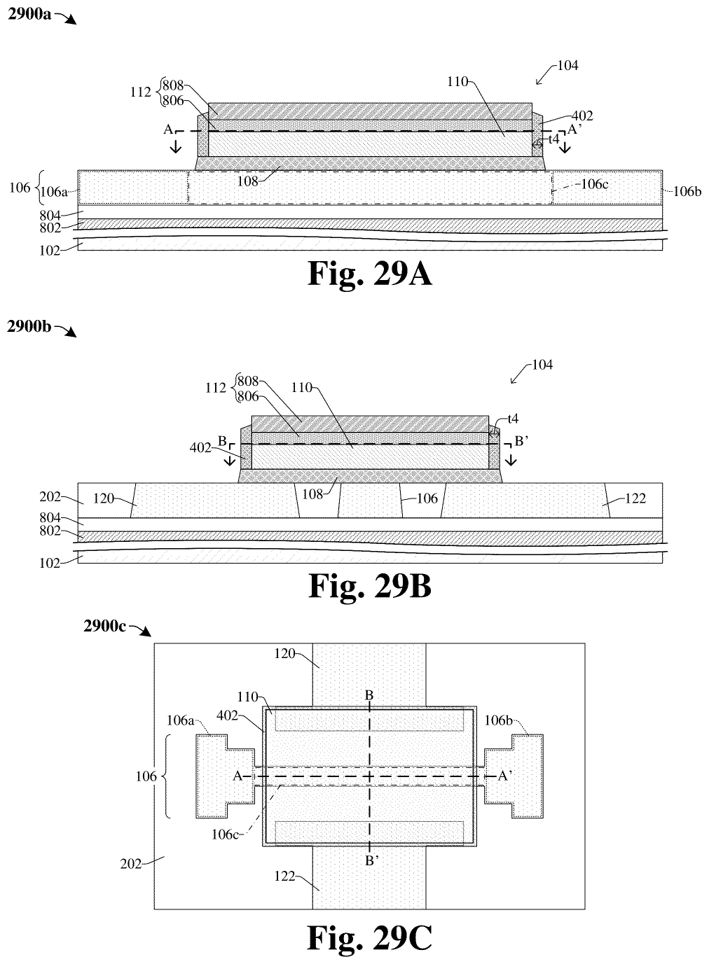

As shown in cross-sectional views 2900a-b and top view 2900c of FIGS. 29A-29C, a sidewall spacer structure 402 is formed along outer opposing sidewalls of the PCE 110. The sidewall spacer structure 402 has a fourth thickness t4 that may, for example, be within a range of about 200 angstroms to 600 angstroms, or some other suitable value. The sidewall spacer structure 402 may, for example, be or comprise silicon nitride, silicon carbide, a non-oxygen based dielectric material, another dielectric material, or any combination of the foregoing. In some embodiments, a process for forming the sidewall spacer structure 402 comprises: depositing (e.g., by CVD, PVD, ALD, etc.) a sidewall spacer layer over the PCM device 104 and performing an etching process on the sidewall spacer layer, the thermal barrier structure 108, and the thermal barrier layer (2502 of FIGS. 28A-28C). In various embodiments, the etching process comprises a dry etch, a wet etch, or any combination of the foregoing. In yet further embodiments, the etching process removes the thermal barrier layer (2502 of FIGS. 28A-28C) from over the first and second RF structures 120, 122. It will be appreciated that for ease of illustration the sidewall spacer structure 402 and the PCE 110 are partially transparent in the top view 2900c of FIG. 29C.

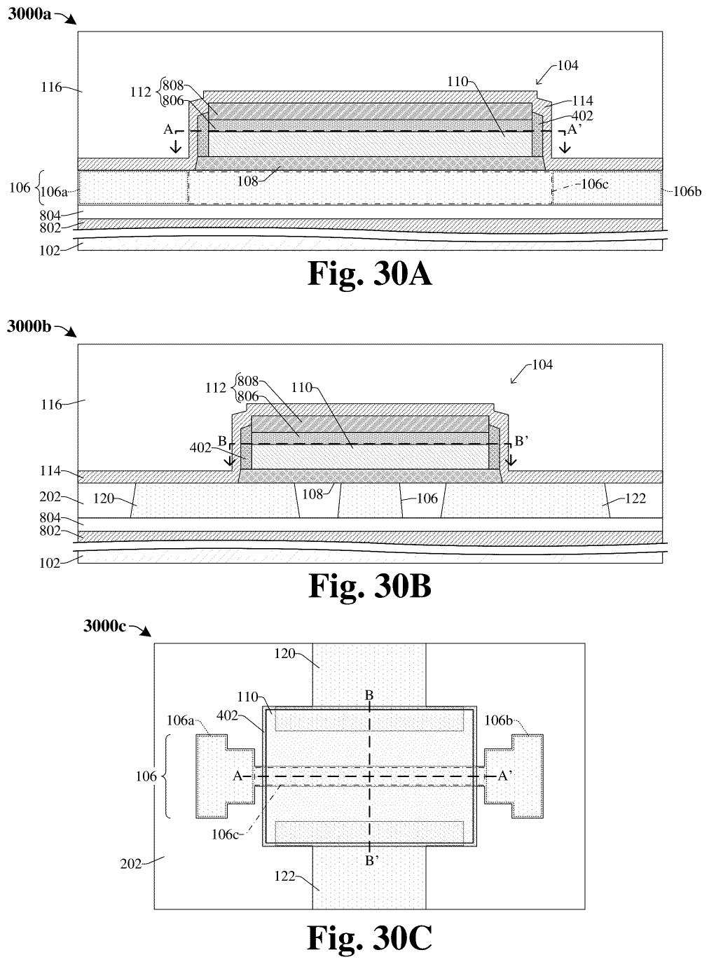

As shown in cross-sectional views 3000a-b and top view 3000c of FIGS. 30A-30C, a capping layer 114 and an upper dielectric layer 116 are formed over the PCM device 104. In some embodiments, the capping layer 114 and the upper dielectric layer 116 may, for example, each be formed by a CVD process, a PVD process, an ALD process, or some other suitable growth or deposition process. It will be appreciated that the capping layer 114 and the upper dielectric layer 116 are omitted from the top view 3000c of FIG. 30C for ease of illustration. In various embodiments, the capping layer 114 may be formed to a thickness within a range of about 100 angstroms to about 400 angstroms, or some other suitable thickness value.

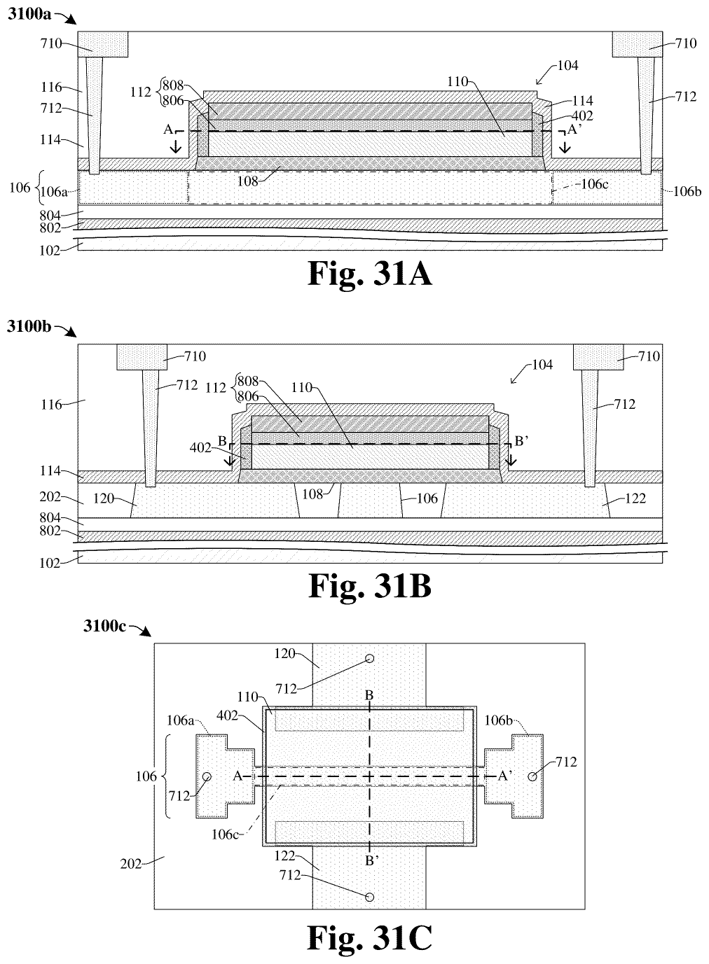

As shown in cross-sectional views 3100a-b and top view 3100c of FIGS. 31A-31C, a plurality of conductive vias 712 and a plurality of conductive wires 710 are formed over the PCM device 104. The conductive wires and vias 710, 712 may, for example, be formed by one or more deposition process(es), one or more patterning process(es), one or more planarization process(es), some other suitable fabrication process(es), or any combination of the foregoing. In some embodiments, a process for forming the conductive wires and vias 710, 712 comprises: patterning the upper dielectric layer 116 and/or the capping layer 114 to form a plurality of metallization openings over the heater structure 106 and the first and second RF structures 120, 122; filling the plurality of metallization openings with a conductive material (e.g., copper, aluminum, titanium nitride, tantalum nitride, ruthenium, another meal material, or any combination of the foregoing); and performing a planarization process (e.g., a CMP process, an etching process, etc.) into the conductive material.

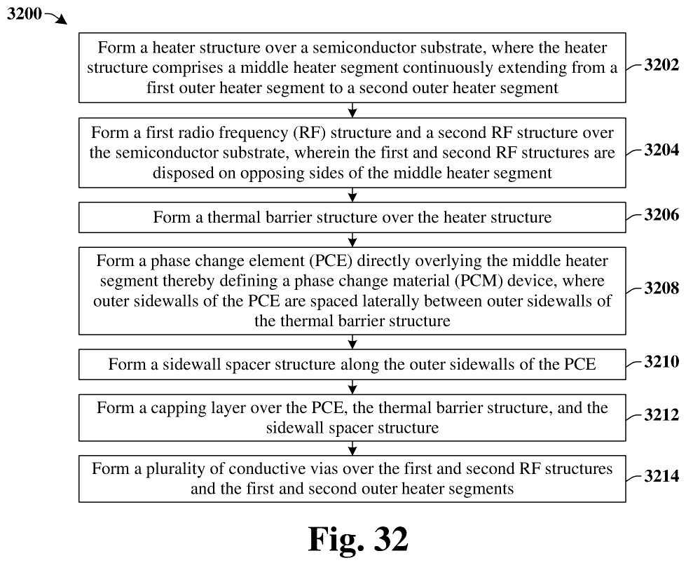

FIG. 32 illustrates a flow diagram of some embodiments of a method 3200 for forming an integrated chip comprising a PCM device having a thermal barrier structure and a sidewall spacer structure configured to increase a performance of the PCM device. Although the method 3200 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 3202, a heater structure is formed over a semiconductor substrate. The heater structure comprises a middle heater segment continuously laterally extending from a first outer heater segment to a second outer heater segment. FIGS. 25A-25C illustrate various views corresponding to some embodiments of act 3202.

At act 3204, a first radio frequency (RF) structure and a second RF structure are formed over the semiconductor substrate, where the first and second RF structures are disposed on opposing sides of the middle heater segment. FIGS. 25A-25C illustrate various views corresponding to some embodiments of act 3204.

At act 3206, a thermal barrier structure is formed over the heater structure. FIGS. 25A-25C through 26A-26C illustrate various views corresponding to some embodiments of act 3206.

At act 3208, a phase change element (PCE) is formed directly overlying the middle heater segment thereby defining a PCM device, where outer sidewalls of the PCE are spaced laterally between outer sidewalls of the thermal barrier structure. FIGS. 27A-27C through 28A-28C illustrate various views corresponding to some embodiments of act 3208.

At act 3210, a sidewall spacer structure is formed along the outer sidewalls of the PCE. FIGS. 29A-29C illustrate various views corresponding to some embodiments of act 3210.

At act 3212, a capping layer is formed over the PCE, the thermal barrier structure, and the sidewall spacer structure. FIGS. 30A-30C illustrate various views corresponding to some embodiments of act 3212.

At act 3214, a plurality of conductive vias is formed over the first and second RF structures and the first and second outer heater segments. FIGS. 31A-C illustrate various views corresponding to some embodiments of act 3214.

Accordingly, in some embodiments, the present application relates to a PCM device comprising a thermal barrier structure disposed between a heater structure and a PCE, where outer sidewalls of the PCE are spaced laterally between outer sidewalls of the thermal barrier structure.

In various embodiments, the present application provides an integrated chip including: a heater structure overlying a semiconductor substrate; a phase change element (PCE) disposed over the heater structure; and a thermal barrier structure disposed between the heater structure and the PCE, wherein outer sidewalls of the PCE are spaced laterally between outer sidewalls of the thermal barrier structure. In an embodiment, the thermal barrier structure comprises a first outer heater segment, a second outer heater segment, and a middle heater segment continuously laterally extending from the first outer heater segment to the second outer heater segment, wherein widths of the first and second outer heater segments are greater than a width of the middle heater segment. In an embodiment, the PCE directly overlies the middle heater segment and wherein a length of the middle heater segment is greater than a length of the PCE. In an embodiment, a width of the PCE is greater than the width of the middle heater segment. In an embodiment, the integrated chip further includes: a first radio frequency (RF) structure overlying the semiconductor substrate; and a second RF structure overlying the semiconductor substrate, wherein the first and second RF structures are disposed on opposing sides of the middle heater segment, wherein the PCE directly overlies outer regions of the first and second RF structures. In an embodiment, when viewed from above the heater structure and the thermal barrier structure have a first shape and the PCE has a second shape different from the first shape, wherein an area of the heater structure is greater than an area of the thermal barrier structure. In an embodiment, the integrated chip further includes: a sidewall spacer structure disposed on the outer sidewalls of the PCE, wherein the sidewall spacer structure contacts a top surface of the thermal barrier structure. In an embodiment, the sidewall spacer structure and the thermal barrier structure respectively comprise a non-oxygen based dielectric material.

In various embodiments, the present application provides an integrated chip, including: a lower dielectric layer overlying a semiconductor substrate; a heater structure disposed within the lower dielectric layer, wherein the heater structure comprises a middle heater segment; a phase change element (PCE) overlying the heater structure; and a thermal barrier structure vertically between the heater structure and the PCE, wherein the thermal barrier structure continuously laterally extends from an outer edge of the PCE to directly over an outer region of the middle heater segment. In an embodiment, the integrated chip further includes: a sidewall spacer structure laterally wrapped around the PCE, wherein the sidewall spacer structure directly overlies at least a portion of the outer region of the middle heater segment. In an embodiment, the integrated chip further includes: a capping layer overlying the PCE, wherein the capping layer continuously extends from over the PCE, along sidewalls of the sidewall spacer structure, to a top surface of the heater structure. In an embodiment, the integrated chip further includes; a hard mask disposed on the PCE, wherein the sidewall spacer structure continuously extends from opposing sidewalls of the PCE to opposing sidewalls of the hard mask. In an embodiment, a top surface of the hard mask is aligned with a top surface of the sidewall spacer structure. In an embodiment, when viewed from above the PCE and the thermal barrier structure have a first shape and the heater structure has a second shape different from the first shape, wherein an area of the heater structure is greater than an area of the PCE. In an embodiment, the heater structure further comprises a first outer heater segment and a second outer heater segment disposed on opposing sides of the middle heater segment, wherein the first and second outer heater segments each have two or more discrete widths greater than a width of the middle heater segment.

In various embodiments, the present application provides a method for forming an integrated chip, the method including: forming a heater structure over a semiconductor substrate; depositing a thermal barrier layer over the heater structure; performing a first patterning process on the thermal barrier layer to form a thermal barrier structure over the heater structure; depositing a phase change element (PCE) layer over the thermal barrier structure; and performing a second patterning process on the PCE layer to form a PCE over the thermal barrier structure, where a length of the thermal barrier structure is greater than a length of the PCE. In an embodiment, the first patterning process is different from the second patterning process. In an embodiment, the first patterning process comprises forming a first mask over the thermal barrier layer and the second patterning process comprises forming a second mask over the PCE layer, wherein the first mask is different from the second mask. In an embodiment, the method further includes forming a first radio frequency (RF) structure and a second RF structure over the semiconductor substrate, wherein the heater structure is spaced laterally between the first and second RF structures, wherein the heater structure and the first and second RF structures are formed concurrently with one another. In an embodiment, the method further includes forming a sidewall spacer structure along outer opposing sidewalls of the PCE, wherein the sidewall spacer structure continuously extends from a top surface of the thermal barrier structure to the outer opposing sidewalls of the PCE.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a heater structure overlying a semiconductor substrate;
a phase change element (PCE) disposed over the heater structure; and
a thermal barrier structure disposed between the heater structure and the PCE, wherein outer sidewalls of the PCE are spaced laterally between outer sidewalls of the thermal barrier structure.

2. The integrated chip of claim 1, wherein the thermal barrier structure comprises a first outer heater segment, a second outer heater segment, and a middle heater segment continuously laterally extending from the first outer heater segment to the second outer heater segment, wherein widths of the first and second outer heater segments are greater than a width of the middle heater segment.

3. The integrated chip of claim 2, wherein the PCE directly overlies the middle heater segment and wherein a length of the middle heater segment is greater than a length of the PCE.

4. The integrated chip of claim 3, wherein a width of the PCE is greater than the width of the middle heater segment.

5. The integrated chip of claim 2, further comprising:
a first radio frequency (RF) structure overlying the semiconductor substrate; and
a second RF structure overlying the semiconductor substrate, wherein the first and second RF structures are disposed on opposing sides of the middle heater segment, wherein the PCE directly overlies outer regions of the first and second RF structures.

6. The integrated chip of claim 1, wherein when viewed from above the heater structure and the thermal barrier structure have a first shape and the PCE has a second shape different from the first shape, wherein an area of the heater structure is greater than an area of the thermal barrier structure.

7. The integrated chip of claim 1, further comprising:
a sidewall spacer structure disposed on the outer sidewalls of the PCE, wherein the sidewall spacer structure contacts a top surface of the thermal barrier structure.

8. The integrated chip of claim 7, wherein the sidewall spacer structure and the thermal barrier structure respectively comprise a non-oxygen based dielectric material.

9. An integrated chip, comprising:
a lower dielectric layer overlying a semiconductor substrate;
a heater structure disposed within the lower dielectric layer, wherein the heater structure comprises a middle heater segment;
a phase change element (PCE) overlying the heater structure; and
a thermal barrier structure vertically between the heater structure and the PCE, wherein the thermal barrier structure continuously laterally extends from an outer edge of the PCE to directly over an outer region of the middle heater segment.

10. The integrated chip of claim 9, further comprising:
a sidewall spacer structure laterally wrapped around the PCE, wherein the sidewall spacer structure directly overlies at least a portion of the outer region of the middle heater segment.

11. The integrated chip of claim 10, further comprising:
a capping layer overlying the PCE, wherein the capping layer continuously extends from over the PCE, along sidewalls of the sidewall spacer structure, to a top surface of the heater structure.

12. The integrated chip of claim 10, further comprising:
a hard mask disposed on the PCE, wherein the sidewall spacer structure continuously extends from opposing sidewalls of the PCE to opposing sidewalls of the hard mask.

13. The integrated chip of claim 12, wherein a top surface of the hard mask is aligned with a top surface of the sidewall spacer structure.

14. The integrated chip of claim 9, wherein when viewed from above the PCE and the thermal barrier structure have a first shape and the heater structure has a second shape different from the first shape, wherein an area of the heater structure is greater than an area of the PCE.

15. The integrated chip of claim 9, wherein the heater structure further comprises a first outer heater segment and a second outer heater segment disposed on opposing sides of the middle heater segment, wherein the first and second outer heater segments each have two or more discrete widths greater than a width of the middle heater segment.

16. A method for forming an integrated chip, the method comprising:
forming a heater structure over a semiconductor substrate;
depositing a thermal barrier layer over the heater structure;
performing a first patterning process on the thermal barrier layer to form a thermal barrier structure over the heater structure;
depositing a phase change element (PCE) layer over the thermal barrier structure; and
performing a second patterning process on the PCE layer to form a PCE over the thermal barrier structure, where a length of the thermal barrier structure is greater than a length of the PCE.

17. The method of claim 16, wherein the first patterning process is different from the second patterning process.

18. The method of claim 17, wherein the first patterning process comprises forming a first mask over the thermal barrier layer and the second patterning process comprises forming a second mask over the PCE layer, wherein the first mask is different from the second mask.

19. The method of claim 16, further comprising:
forming a first radio frequency (RF) structure and a second RF structure over the semiconductor substrate, wherein the heater structure is spaced laterally between the first and second RF structures, wherein the heater structure and the first and second RF structures are formed concurrently with one another.

20. The method of claim 16, further comprising:
forming a sidewall spacer structure along outer opposing sidewalls of the PCE, wherein the sidewall spacer structure continuously extends from a top surface of the thermal barrier structure to the outer opposing sidewalls of the PCE.
